(19) United States
(12) Patent Application Publication
(10) Pub. No.: US 2026/0150393 A1
(43) Pub. Date: May 28, 2026

(54) MULTI-GATE DEVICE WITH SOURCE/DRAIN FEATURES HAVING VARIED WIDTHS

(71) Applicant: Taiwan Semiconductor Manufacturing Company, Ltd., Hsin-Chu (TW)

(72) Inventors: Yu-Hsien Chiang, Hsinchu City (TW); Zhi-Chang Lin, Zhubei City (TW); Ku-Feng Yang, Baoshan Township (TW); Szuya Liao, Zhubei (TW)

(21) Appl. No.: 19/189,954

(22) Filed: Apr. 25, 2025

Related U.S. Application Data
(60) Provisional application No. 63/725,791, filed on Nov. 27, 2024.

(51) Int. Cl. H10D 84/85; H10D 30/00; H10D 30/01; H10D 30/43; H10D 62/10; H10D 62/13; H10D 62/40; H10D 62/60; H10D 62/83; H10D 62/834; H10D 64/23; H10D 84/01

(52) U.S. Cl. CPC H10D 84/851; H10D 30/014; H10D 30/0191; H10D 30/43; H10D 30/502; H10D 30/503; H10D 62/121; H10D 62/151; H10D 62/405; H10D 62/60; H10D 62/83; H10D 62/834; H10D 64/256; H10D 84/017; H10D 84/856

(57) ABSTRACT

Semiconductor devices and methods of forming the same are provided. An exemplary method includes forming a semiconductor layer stack over a substrate, the semiconductor layer stack having an upper channel layer over a lower channel layer, performing an etching process to laterally recess the lower channel layer without substantially etching the upper channel layer, forming a first source/drain feature coupled to the recessed lower channel layer, and forming a second source/drain feature coupled to the upper channel layer, the second source/drain feature is disposed over the first source/drain feature.

### PRIORITY DATA

This application claims priority to U.S. Provisional Patent Application Ser. No. 63/725,791, filed Nov. 27, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFETs) where an n-type multi-gate transistor and a p-type multi-gate transistor are stacked vertically, one over the other.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a method for forming a semiconductor device including a vertical CFET, according to one or more aspects of the present disclosure.

FIGS. 3, 4, 5, 6, 7, 8, 9, 10, 11, 12, 13, 14, 15, 16, 17, 18, and 19 illustrate fragmentary cross-sectional views of the semiconductor device during various fabrication stages in the method of FIG. 2, according to various aspects of the present disclosure.

FIG. 20 illustrates a flow chart of a method for forming a multi-gate device, according to one or more aspects of the present disclosure.

FIGS. 21, 22, 23, 24, 25, 26, 27, 28, 29, and 30 illustrate fragmentary cross-sectional views of the semiconductor device during various fabrication stages in the method of FIG. 20, according to various aspects of the present disclosure.

FIG. 31 depicts a fragmentary cross-sectional view of a first alternative semiconductor device, according to various aspects of the present disclosure.

FIG. 32 depicts a fragmentary cross-sectional view of a second alternative semiconductor device, according to various aspects of the present disclosure.

FIG. 33 depicts a fragmentary cross-sectional view of a third alternative semiconductor device, according to various aspects of the present disclosure.

FIG. 34 depicts a fragmentary cross-sectional view of a fourth alternative semiconductor device, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (CFET). The multi-gate devices in a CFET may be FinFETs or GAA transistors. In an embodiment, the top multi-gate device may be an n-type transistor, and the bottom multi-gate device may be a p-type transistor. Dislocations may form during the epitaxial growth of different epitaxial layers of the p-type source/drain feature. In addition, in some embodiments, a backside via may be formed to couple to the p-type source/drain feature from its back. The formation of the backside via may include removing a large amount of the p-type source/drain feature to achieve small contact resistance.

The present disclosure provides methods of forming a source/drain feature having a different profile. In an embodiment, after forming source/drain opening, channel layers may be selectively and laterally recessed. Growth durations for forming different epitaxial layers of the source/drain feature are controlled such that the space for forming a lightly doped epitaxial layer is reduced, and the space for forming a heavily doped epitaxial layer is increased. In addition, parasitic resistance of a semiconductor device including this source/drain feature may be reduced.

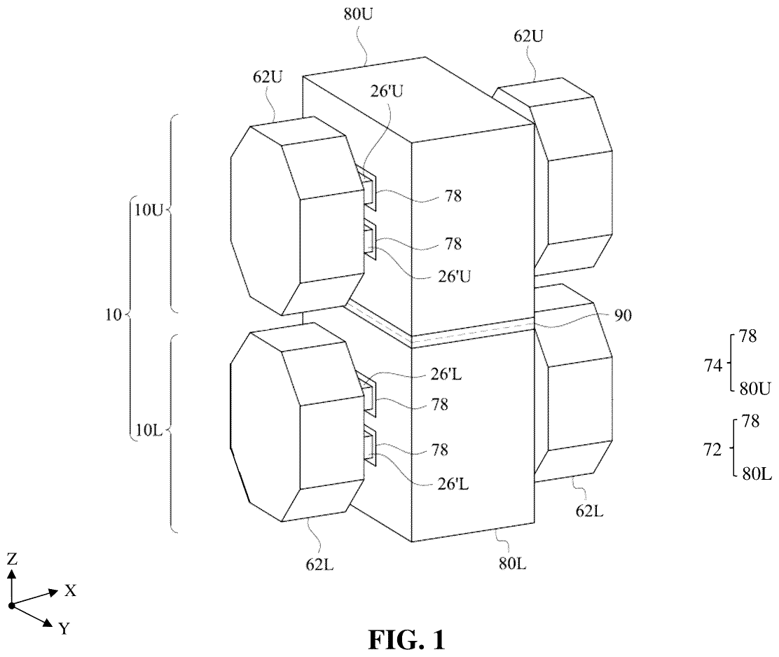

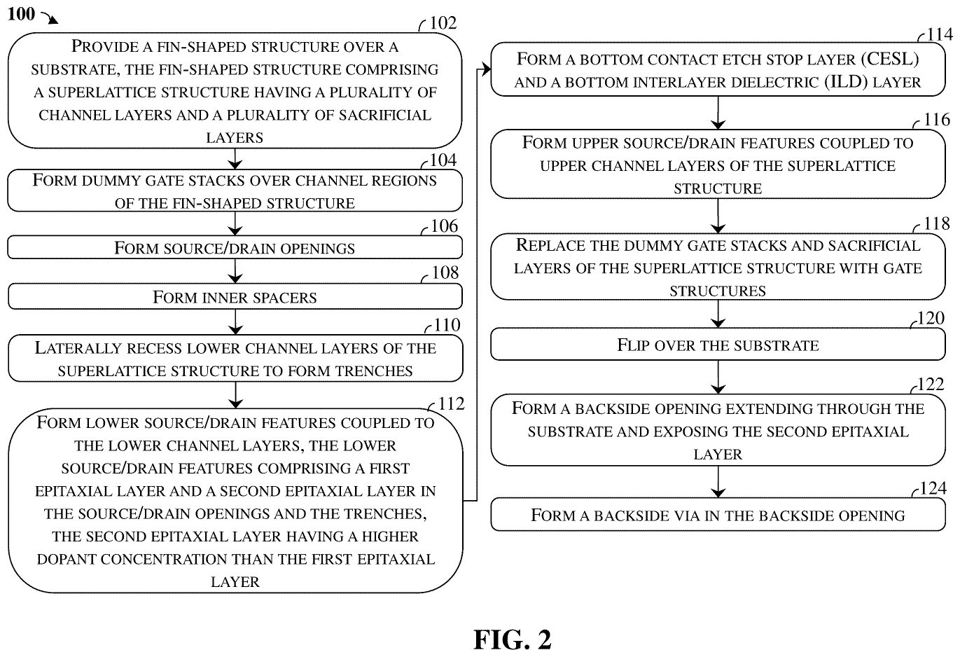

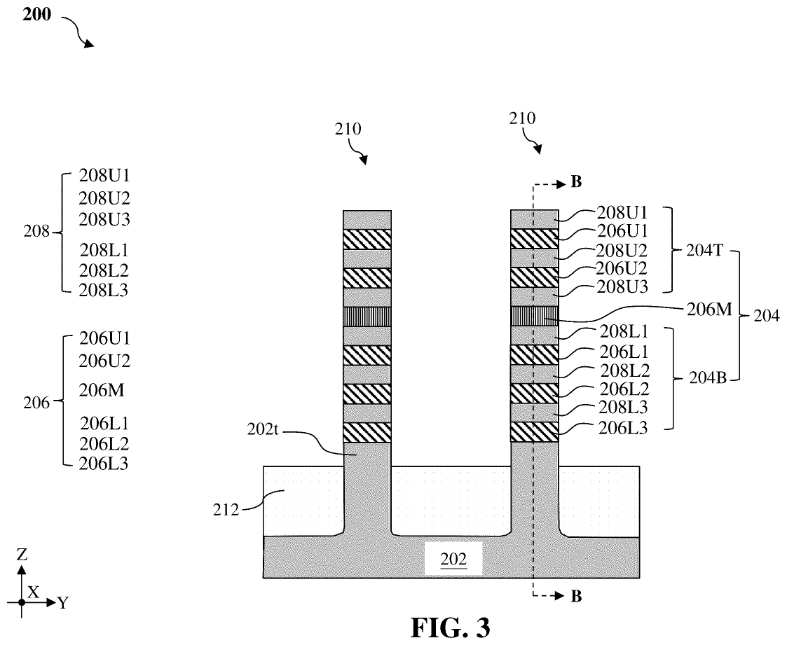

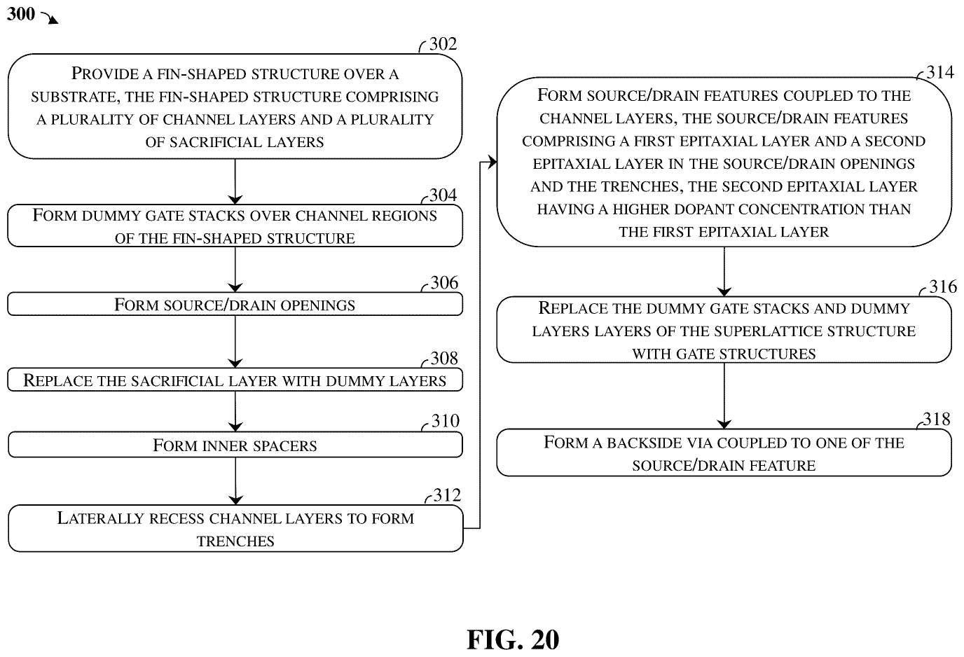

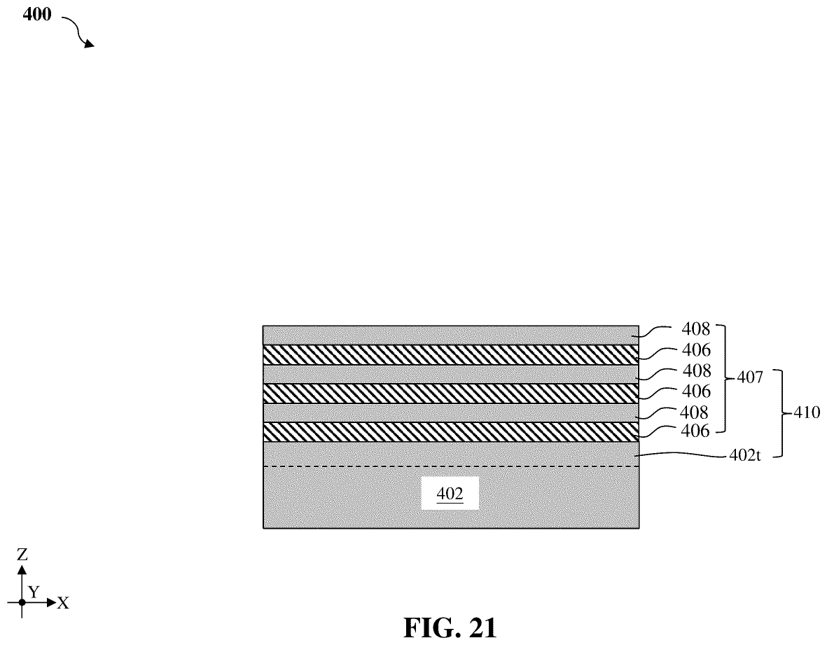

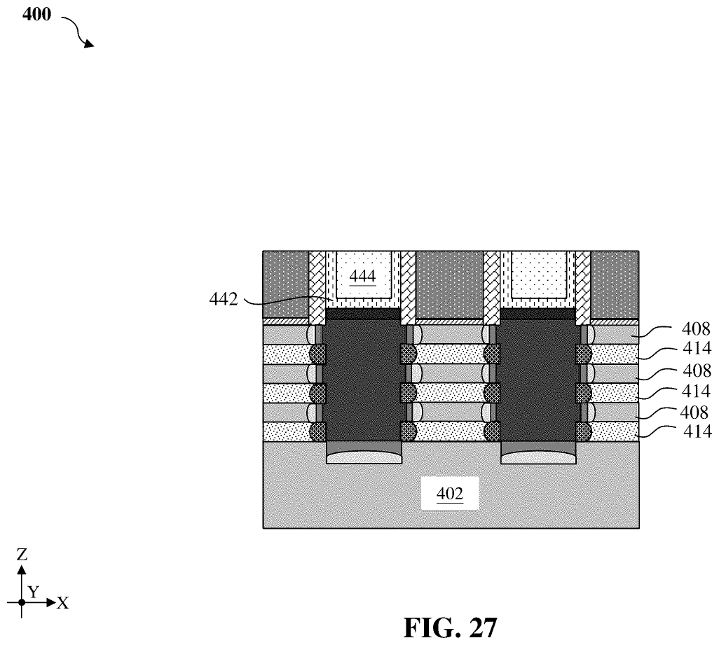

The various aspects of the present disclosure will now be described in more detail with reference to the figures. In that regard, FIG. 1 illustrates a perspective view of a semiconductor device including a vertical CFET, according to one or more aspects of the present disclosure. FIG. 2 illustrates a flow chart of a method 100 for forming a semiconductor device 200 including a vertical CFET, according to one or more aspects of the present disclosure. Method 100 is described below in conjunction with FIGS. 3-19, which are fragmentary cross-sectional views of the semiconductor device 200 at different stages of fabrication according to embodiments of method 100. Intermediate structure of the semiconductor device 200 during the fabrication processes may be referred to as the intermediate structure 200. FIG. 20 illustrates a flow chart of a method 300 for forming a gate-all-around transistor 400. Method 300 is described below in conjunction with FIGS. 21-30, which are fragmentary cross-sectional views of the gate-all-around transistor 400 at different stages of fabrication according to embodiments of method 300. Intermediate structure of the gate-all-around transistor 400 during the fabrication processes may be referred to as the intermediate structure 400. Method 100 and method 300 are merely examples and are not intended to limit the present disclosure to what is explicitly illustrated therein. Additional steps may be provided before, during and after method 100 and method 300, and some steps described can be replaced, eliminated, or moved around for additional embodiments of the method. Not all steps are described herein in detail for reasons of simplicity. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., CFET) 10. The semiconductor device 10 includes a lower device 10L (e.g., p-type transistor) and an upper device 10U (e.g., n-type transistor) over the lower device 10L. The lower device 10L includes channel layers 26′L wrapped around by a bottom gate structure 72. The bottom gate structure 72 includes a gate dielectric layer 78 and a gate electrode 80L. The lower device 10L also includes source/drain features (e.g., p-type epitaxial source/drain features) 62L coupled to the channel layers 26′L and adjacent the bottom gate structure 72.

The upper device 10U includes channel layers 26′U wrapped around by an upper gate structure 74. The upper gate structure 74 includes the gate dielectric layer 78 and a gate electrode 80U. The upper device 10U also includes source/drain features (e.g., n-type epitaxial source/drain features) 62U coupled to the channel layers 26′U and adjacent the upper gate structure 74. An isolation layer 90 is disposed between the upper device 10U and the lower device 10L to electrically insulate the upper gate structure 74 of the upper device 10U from the bottom gate structure 72 of the lower device 10L. The configurations of the elements in the semiconductor device 10 described above are given for illustrative purposes and can be modified depending on the actual implementations. It is understood that some features are omitted in this figure for reason of simplicity.

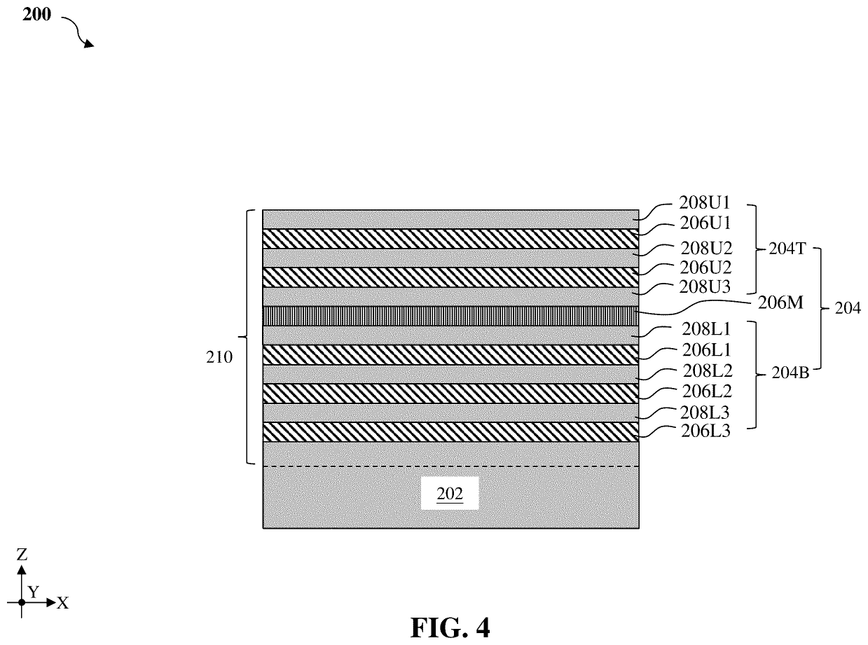

Referring now to FIGS. 2 and 3-4, method 100 includes a block 102 where an intermediate structure 200 is received. FIG. 3 depicts a cross-sectional view of the intermediate structure 200, and FIG. 4 depicts a cross-sectional view of the intermediate structure 200 taken along line B-B shown in FIG. 3. The intermediate structure 200 includes a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The intermediate structure 200 also includes fin-shaped structures 210 protruding from the substrate 202. In the present embodiments, the fin-shaped structure 210 is formed from a superlattice structure 204 and a portion of the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a number of channel layers 208 interleaved by a number of sacrificial layers 206. The sacrificial layers 206 and the channel layers 208 are deposited alternatingly, one-after-another, to form the superlattice structure 204. The channel layers 208 and the sacrificial layers 206 may have different semiconductor compositions. In some implementations, the channel layers 208 are formed of silicon (Si) and sacrificial layers 206 are formed of silicon germanium (SiGe). Precursors for forming the channel layers 208 may include silane, dichloride silane, germane, digermane, tetrachloride germane, diborane, boron trichloride, and/or or HCl. In these implementations, the additional germanium content in the sacrificial layers 206 allows selective removal or recess of the sacrificial layers 206 without inducing substantial damages to the channel layers 208.

For ease of references, the superlattice structure 204 may be vertically divided into a bottom portion 204B, a middle sacrificial layer 206M on the bottom portion 204B, and a top portion 204T on the middle sacrificial layer 206M. In this depicted example, the bottom portion 204B of the superlattice structure 204 includes channel layers 208L 1, 208L2 and 208L3 interleaved by sacrificial layers 206L1, 206L2, and 206L3. The top portion 204T of the superlattice structure 204 includes channel layers 208U 1, 208U 2 and 208U 3 interleaved by sacrificial layers 20601 and 206U2. The channel layers 208L1, 208L2, 208L 3, 208U1, 208U2, and 208U 3 will provide nanostructures for the CFET. In some embodiments, the channel layers 208U 1-208U2 will provide channel members for a top GAA transistor of the CFET, and the channel layers 208L2-208L3 will provide channel members for a bottom GAA transistor in the CFET. The term “channel member(s)” is used herein to designate any material portion for channel(s) in a transistor with nanoscale dimensions, and having an elongate shape, regardless of the cross-sectional shape of this portion. A germanium content of the middle sacrificial layer 206M may be different from the germanium content of other sacrificial layers (e.g., sacrificial layers 206U 1-206U 2, sacrificial layers 206L 1-206L 3) of the top portion 204T and bottom portion 204B. In some embodiments, a germanium content of the middle sacrificial layer 206M is greater than a germanium content of the other sacrificial layers 206U 1-206U 2 and 206L1-206L3 such that the entirety of the middle sacrificial layer 206M may be selectively removed during the formation of inner spacer recesses. It is noted that the superlattice structure 204 in FIGS. 3-4 includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed within the bottom portion 204B and the top portion 204T. The number of layers depends on the desired number of channels members for the top GAA transistor and the bottom GAA transistor. In some embodiments, the number of the channel layers 208 in the superlattice structure 204 may be between 4 and 10.

The superlattice structure 204 and a portion of the substrate 202 are then patterned to form the fin-shaped structures 210. The patterned portion of the substrate 202 may be referred to as a protrusion 202t. The protrusion 202t may also be referred to as a mesa or a base fin in some embodiments. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 3-4, each fin-shaped structure 210 extends vertically along the Z direction from the substrate 202 and extends lengthwise along the X direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

The intermediate structure 200 also includes an isolation feature 212 (shown in FIG. 3) formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the intermediate structure 200, including the fin-shaped structure 210, using CVD, subatmospheric CVD (SACVD), flowable CVD, spin-on coating, and/or other suitable process. Then, the deposited dielectric material is planarized and recessed to form the isolation feature 212. As shown in FIG. 3, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials.

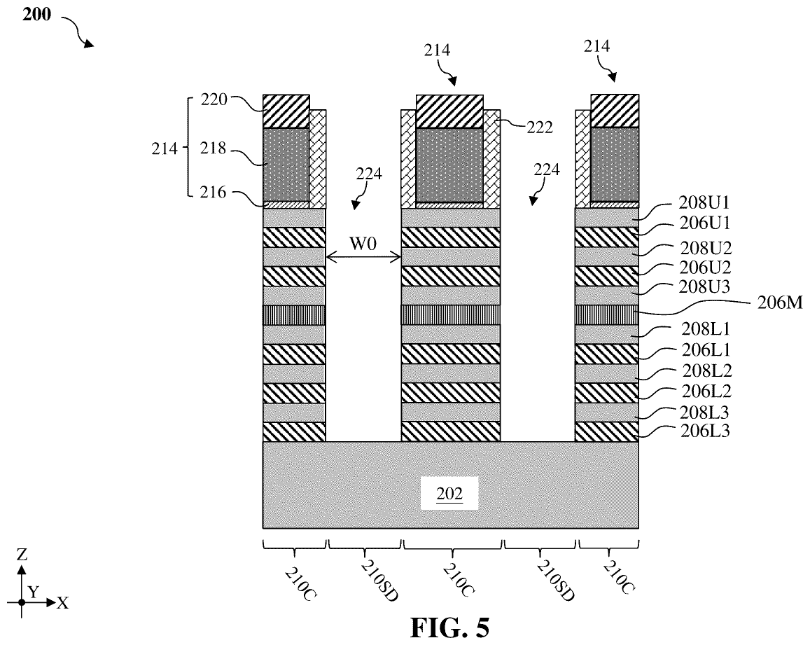

Referring to FIGS. 2 and 5, method 100 includes a block 104 where dummy gate stacks 214 are formed over channel regions 210C of the fin-shaped structure 210. In some embodiments, a gate replacement process (or gate-last process) is adopted where the dummy gate stack 214 serves as a placeholder for a functional gate structure. Other processes and configurations are possible. To form the dummy gate stack 214, a dummy dielectric layer 216, a dummy gate electrode layer 218, and a gate-top hard mask layer 220 are deposited over the intermediate structure 200. The deposition of these layers may include use of chemical vapor deposition (CVD), low-pressure CVD (LPCVD), plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer structure that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode layer 218 are then etched to form the dummy gate stack 214. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source and/or a drain region for forming a drain, individually or collectively dependent upon the context.

Still referring to FIGS. 2 and 5, method 100 includes a block 106 where source/drain regions 210SD of the fin-shaped structure 210 are recessed to form source/drain openings 224. Operations at block 106 may include formation of gate spacer 222 over the sidewalls of the dummy gate stack 214 before the source/drain regions 210SD are recessed. In some embodiments, the formation of the gate spacer 222 includes deposition of one or more dielectric layers over the intermediate structure 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the formation of the gate spacer 222, an etching process is performed to the intermediate structure 200 to form the source/drain openings 224. The etching process at block 106 may be a dry etch process or other suitable etch process. An example dry etching process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the etching process at block 106 does not substantially etch the substrate 202. In some other embodiments, the source/drain openings 224 may extend into the substrate 202. As shown in FIG. 5, sidewalls of the sacrificial layers 206 and the channel layers 208 in the channel regions 210C are exposed in the source/drain openings 224. The source/drain opening 224 spans a width W0.

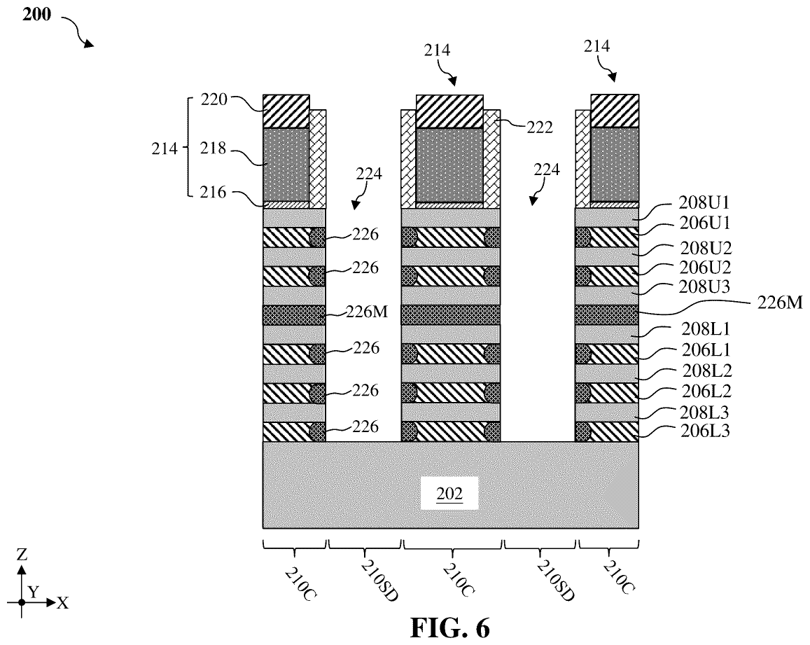

Referring to FIGS. 2 and 6, method 100 includes a block 108 where inner spacers 226 are formed. At block 108, the sacrificial layers 206 exposed in the source/drain openings 224 are selectively and partially recessed to form inner spacer recesses, while the exposed channel layers 208 are substantially unetched. The middle sacrificial layer 206M, due to its greater germanium content, may be substantially removed during the formation of inner spacer recesses. In some embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the intermediate structure 200, including in the inner spacer recesses. Additionally, as shown in FIG. 6, the inner spacer material layer may also be deposited in the space left behind by selective removal of the middle sacrificial layer 206M. The inner spacer material layer may include silicon oxide, silicon nitride, silicon oxynitride, silicon oxycarbide, silicon oxycarbonitride, silicon carbonitride, or a suitable dielectric material. In an embodiment, the inner spacer material layer includes silicon oxycarbonitride. The deposited inner spacer material layer is then etched back to remove excess portions of the inner spacer material layer over the dummy gate stack 214, the gate spacer 222, and sidewalls of the channel layers 208, thereby forming the inner spacers 226 and the middle dielectric layer 226M, as shown in FIG. 6.

Referring to FIGS. 2 and 7-9, method 100 includes a block 110 where lower channel layers 208L2 and 208L3 are laterally recessed to form trenches 232. In an embodiment, a blocking layer 228 is deposited over the intermediate structure 200 to cover sidewalls of the top portion 204T of the superlattice structure 204. The blocking layer 228 may also cover sidewalls of the middle dielectric layer 226M and the channel layer 208L 1. The blocking layer 228 may include dielectric materials. A composition of the blocking layer 228 is different from compositions of the gate spacers 222 and the inner spacers 226 such that the blocking layer 228 may be selectively removed afterwards.

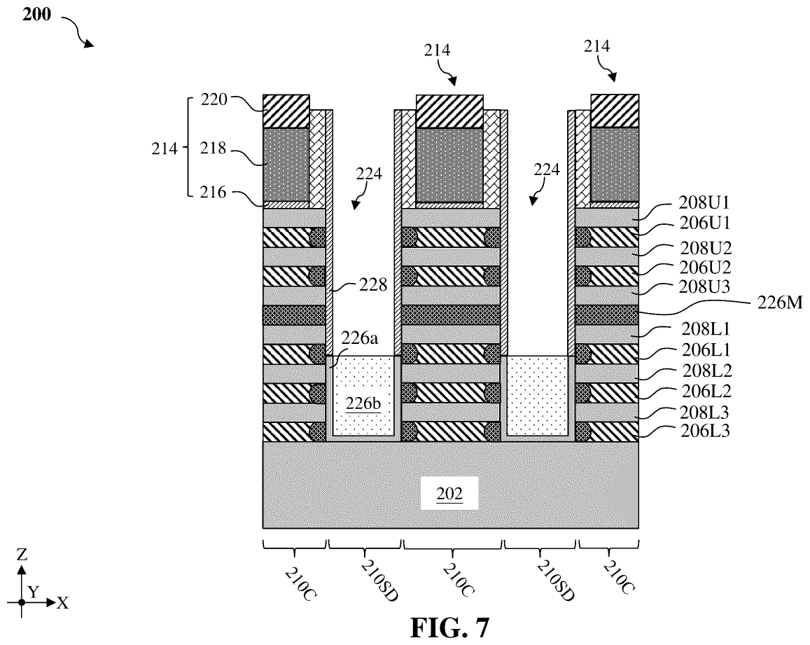

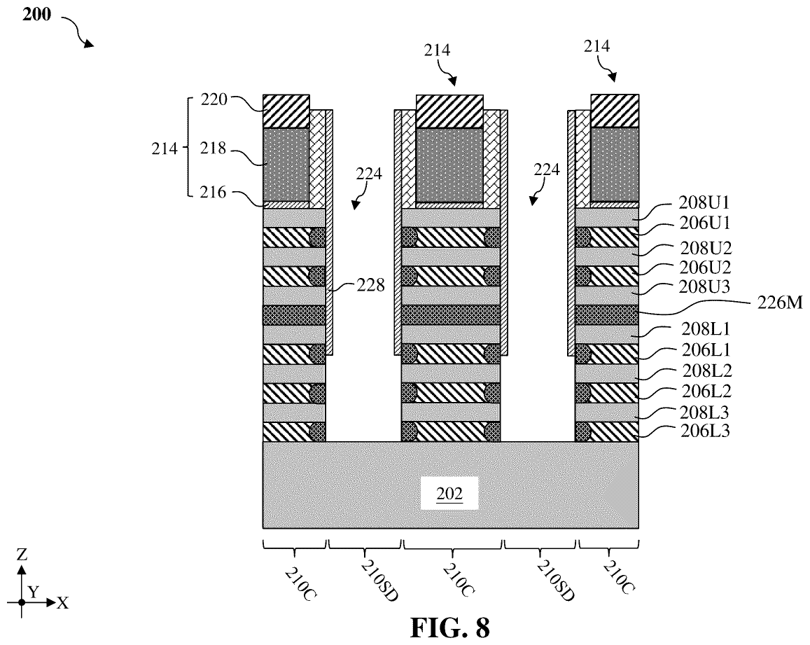

FIGS. 7-8 represent an exemplary method of forming the blocking layer 228. With reference to FIG. 7, after forming the inner spacers 226, a dummy liner 226a is conformally deposited over the intermediate structure 200, including along sidewalls of the source/drain openings 224 and sidewalls and top surfaces of the dummy gate stacks 214. In an example process, the dummy liner 226a is conformally deposited using CV D or ALD. The dummy liner 226a may include a semiconductor material or a dielectric material. In an embodiment, the dummy liner 226a is a silicon layer. After forming the dummy liner 226a, a dummy fill layer 226b is deposited over the dummy liner 226a and in the source/drain openings 224. The dummy fill layer 226b may include one or more dielectric layers deposited using CVD, SACVD, or ALD and may include silicon oxide, silicon nitride, silicon carbide, silicon oxynitride, silicon carbonitride, silicon oxycarbide, silicon oxycarbonitride, and/or combinations thereof. In an embodiment, the dummy fill layer 226b is an oxide layer. After depositing the dummy liner 226a and the dummy fill layer 226b, a first etching process is performed to selectively recess the dummy fill layer 226b until a top surface of the recessed dummy fill layer 226b is below a bottom surface of the channel layer 208L1, as represented by FIG. 7. Then, a second etching process is performed to selectively remove portions of the dummy liner 226a not covered by the recessed dummy fill layer 226b. Thus, upon completion of the first and second etching processes, the lower channel layers 208L 2 and 208L3 are covered by the recessed dummy liner 226a and the recessed dummy fill layer 226b, while sidewalls of the upper channel layers 208U 1-208U 3 and the lower channel layer 208L1 are exposed in the source/drain openings 224.

Still referring to FIG. 7, after covering the lower channel layers 208L2 and 208L3, a dielectric material layer may be then conformally deposited over the substrate 202 using CVD, ALD, or other suitable techniques. The dielectric material layer may include a dielectric material. The dielectric material layer is then etched back to only cover portions of the sidewalls of the source/drain openings 224 that are not covered by the recessed dummy liner 226a and the recessed dummy fill layer 226b. The etched back dielectric material layer forms the blocking layers 228 in the source/drain openings 224. With reference to FIG. 8, after forming the blocking layers 228, the recessed dummy liner 226a and the recessed dummy fill layer 226b may be selectively removed to expose the lower channel layers 208L2 and 208L3.

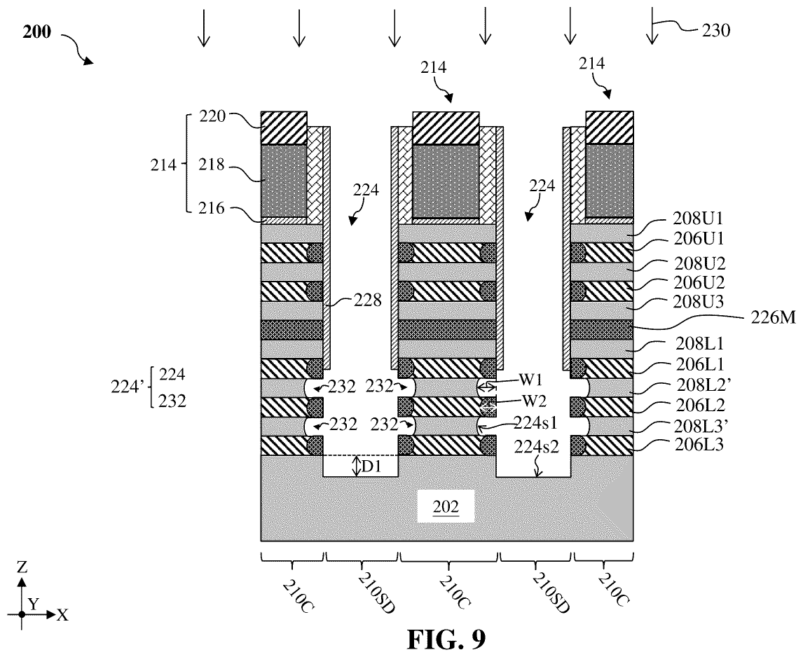

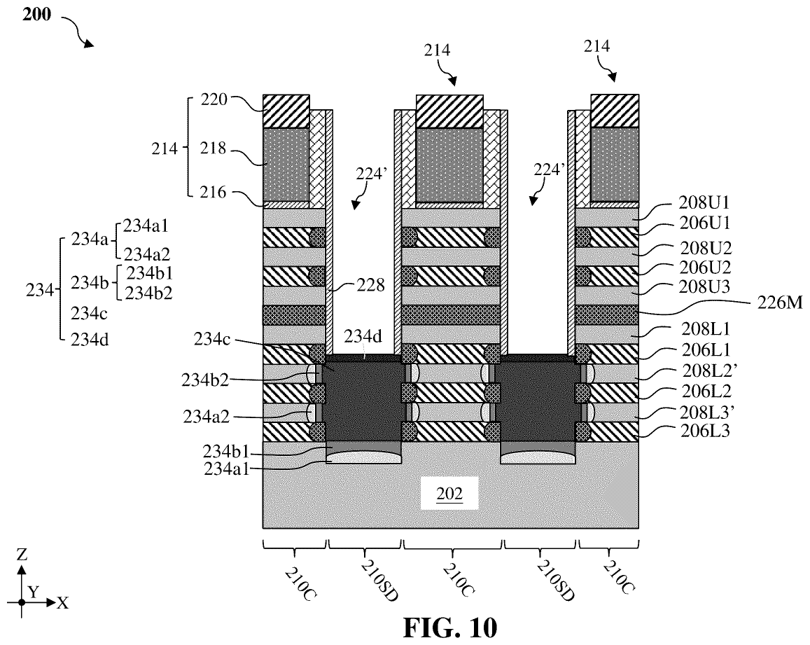

Referring to FIGS. 2 and 9, method 100 includes a block 110 where lower channel layers 208L2 and 208L3 are laterally recessed to form trenches 232. After forming the blocking layer 228 covering the channel layers 208U 1-208U 3 and 208L 1, an etching process 230 is performed to selectively and partially recess the lower channel layers 208L 2-208L 3 to form the trenches 232, while the exposed inner spacers 226 and the blocking layer 228 are not significantly etched. The etching process 230 may be a selective isotropic etching process. The trench 232 spans a width W1. In an embodiment, the inner spacer 226 spans a width W2, and a ratio of the width W1 to the width W2 (i.e., W1/W2) is about 0.6 to about 1.2. If the ratio is less than about 0.6, then the trench may be not large enough to satisfactorily form subsequent epitaxial layers (e.g., portions 234a2 and 234b2 shown in FIG. 10); if the ratio is greater than about 1.2, then the extent at which the lower channel layers 208L2-208L3 is recessed may be too much, disadvantageously increasing the incidence of short channel effect for the bottom multi-gate device. In an embodiment, the width W2 is about 3 nm to about 7 nm, and the width W1 is about 4 nm to about 7 nm. If the width W2 is less than about 3 nm, the inner spacer 226 may be too thin to provide satisfactory isolation between the source/drain features and gate structures; and if the width W2 is greater than 7 nm, the resulted sacrificial layers may have shortened lengths, and thus gate structures that will replace the sacrificial layers may have smaller gate lengths, adversely affecting gate control ability. The trench 232 exposes surfaces of the two inner spacers 226 disposed vertically adjacent to the trench 232. The recessed lower channel layers 208L 2 and 208L 3 may be referred to as the lower channel layers 208L2′ and 208L3′, respectively. In an embodiment, the width of the lower channel layers 208L2′ and 208L3′ is less than the widths of each of the channel layers 208U 1-208U 3 and 208L 1. In an embodiment, since the etching process 230 is an isotropic etching process, the etching process 230 may also remove a portion of the substrate 202 exposed by the source/drain opening 224.

The source/drain openings 224 and the trenches 232 may be collectively referred to as source/drain openings 224′. Upon completion of the etching process 230, in comparison with the source/drain openings 224, the lower portion of the source/drain opening 224′ is both laterally extended (i.e., due to the formation of trenches 232) and vertically extended (i.e., due to the recess of the substrate 202). The width of the lower portion of the source/drain opening 224′ may be substantially equal to a sum of the width W0 and twice of the width W1 of the trench 232 (i.e., W0+2*W1). In an embodiment, the lower channel layers 208L2′-208L3′ and the substrate 202 are formed of silicon. The source/drain opening 224′ exposes sidewall surfaces 224s1 of the lower channel layers 208L2′-208L3′ and a top surface 224s2 of the substrate 202. The sidewall surfaces 224s1 of the lower channel layers 208L2′-208L3′ have a crystal orientation (110) and/or a crystal orientation (111), depending on specific etchant of the etching process 230 and the profile of the trenches 232. The top surface 224s2 of the substrate 202 has a crystal orientation (100) that is different from the crystal orientation of the sidewall surfaces 224s1. In another alternative embodiment, the top surface 224s2 is a concave surface that curves inward. In an embodiment, a distance D1 between the top surface 224s2 of the substrate 202 and a bottommost surface of the superlattice structure 204 is greater than the width W1. In an embodiment, the distance D1 is about 3 nm to about 10 nm.

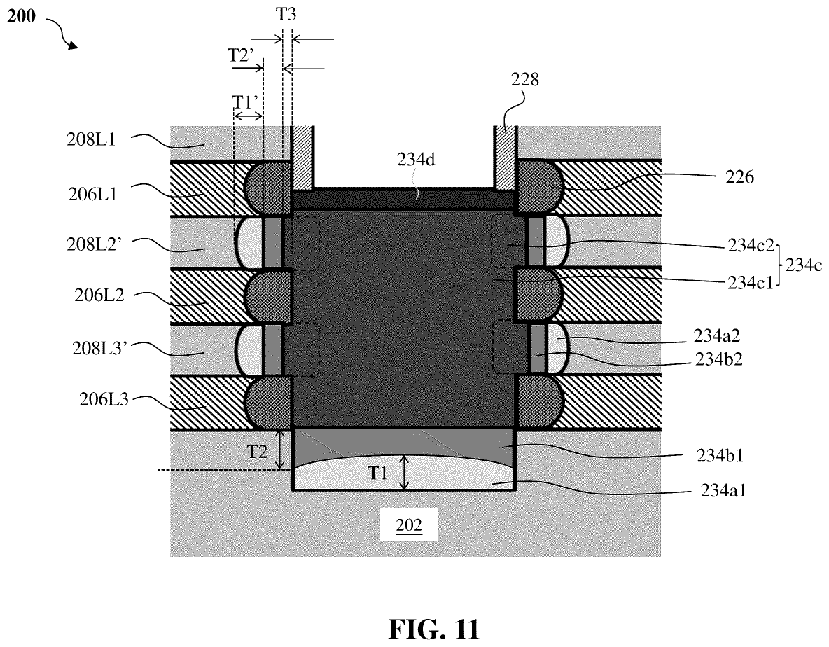

Referring to FIGS. 2 and 10-11, method 100 includes a block 112 where lower source/drain features 234 are formed the source/drain openings 224′. FIG. 11 depicts an enlarged portion of the intermediate structure 200 including the lower source/drain feature 234. After the formation of the trenches 232, lower source/drain features 234 are formed in the source/drain openings 224′, including in the trenches 232. The blocking layer 228, due to its dielectric composition, blocks formation of the lower source/drain features 234 on sidewalls of the channel layers 208U 1-208U 3 and 208L 1. In the present embodiment, the lower source/drain feature 234 is a p-type source/drain feature and includes multiple doped epitaxial layers, such as epitaxial layers 234a, 234b, 234c, and 234d. The epitaxial layers 234a, 234b, 234c, and 234d are formed in a sequential order. More specifically, a first epitaxial process is performed to form the epitaxial layer 234a, a second epitaxial process is performed to form the epitaxial layer 234b after forming the epitaxial layer 234a, a third epitaxial process is performed to form the epitaxial layer 234c after forming the epitaxial layer 234b, and a fourth epitaxial process is performed to form the epitaxial layer 234d after forming the epitaxial layer 234c.

To form the epitaxial layer 234a, the first epitaxial process, such as VPE, UHV-CVD, MBE, and/or other suitable processes, is performed. The first epitaxial growth process may use gaseous and/or liquid precursors (e.g., silane, diiodosilane, disilane, diborane, boron trichloride, HCl), which interact with the composition of the substrate 202 as well as the channel layers 208L2′-208L3′. The epitaxial layer 234a may include boron-doped silicon, gallium-doped silicon or other suitable material and may be in-situ doped during the epitaxial process by introducing a p-type dopant, such as boron or gallium, or ex-situ doped using a junction implant process. In an embodiment, the epitaxial layer 234a is formed of boron-doped silicon, and boron concentration may be between about 1E20 atoms/cm³ and 6E21 atoms/cm³. The first epitaxial process of the epitaxial layer 234a take places from both the exposed sidewalls 224s1 of the lower channel layers 208L2′ and 208L3′ and the exposed top surface 224s2 of the substrate 202. For example, the epitaxial layer 234a includes a portion 234a1 epitaxially grown from the exposed top surface 224s2 of the substrate 202 and a portion 234a2 epitaxially grown from the exposed sidewalls of the lower channel layers 208L2′ and 208L3′. Since a growth rate from (100) direction is greater than a growth rate from (110) direction and (111) direction, upon completion of the first epitaxial process, a thickness T1 of the portion 234al may be greater than a thickness T1′ of the portion 234a2. In an embodiment, the thickness T1′ is about 1 nm to about 3 nm. It is noted that the portion 234a2 partially fills the trench 232. In some embodiments, a top surface of the portion 234a1 is below the bottommost surface of the superlattice structure 204.

To form the epitaxial layer 234b, the second epitaxial process, such as VPE, UHV-CVD, MBE, and/or other suitable processes, is performed. The second epitaxial growth process may use gaseous and/or liquid precursors (e.g., silane, dichloride silane, disilane, diiodosilane, iodosilane, disilane, germane, digermane, diiodogermane, iodogermane, tetrachloride), which interact with the composition of the portion 234al as well as the portion 234a2. The epitaxial layer 234b may include boron-doped silicon germanium, gallium-doped silicon germanium or other suitable material and may be in-situ doped during the epitaxial process by introducing a p-type dopant, such as boron or gallium, or ex-situ doped using a junction implant process. In an embodiment, the epitaxial layer 234b is formed of boron-doped silicon germanium. Boron concentration of the epitaxial layer 234b may be between about 1E20 atoms/cm³ and 6E21 atoms/cm³, germanium concentration of the epitaxial layer 234b is about 10% to about 30%. The second epitaxial process of the epitaxial layer 234b take places from both the exposed sidewalls of the portion 234a2 and the exposed top surface of the portion 234a1. For example, the epitaxial layer 234b includes a portion 234b1 epitaxially grown from the exposed top surface of the 234al and a portion 234b2 epitaxially grown from the exposed sidewalls of the portion 234a2. Since a growth rate from (100) direction is greater than a growth rate from (110) direction and (111) direction, upon completion of the second epitaxial process, a thickness T2 of the portion 234b1 may be greater than a thickness T2′ of the portion 234b2. In some embodiments, a top surface of the portion 234b1 may be substantially coplanar with or below the bottommost surface of the superlattice structure 204. In an embodiment, the thickness T2′ is about 2 nm to about 5 nm. It is noted that, upon completion of the second epitaxial process, the trench 232 is still partially filled. That is, the portion 23462 of the epitaxial layer 234b is confined by the inner spacers 226 and trapped in the trenches 232. Thus, spacing for forming the epitaxial layer 234c is enlarged.

To form the epitaxial layer 234c, the third epitaxial process, such as VPE, UHV-CVD, MBE, and/or other suitable processes, is performed. The third epitaxial growth process may use gaseous and/or liquid precursors (e.g., silane, dichloride silane, disilane, diiodosilane, iodosilane, disilane, germane, digermane, diiodogermane, iodogermane, tetrachloride), which interact with the composition of the portion 234b1 as well as the portion 234b2. The epitaxial layer 234c may include boron-doped silicon germanium, gallium-doped silicon germanium or other suitable material and may be in-situ doped during the epitaxial process by introducing a p-type dopant, such as boron or gallium, or ex-situ doped using a junction implant process. In an embodiment, the epitaxial layer 234c is formed of boron-doped silicon germanium. Boron concentration of the epitaxial layer 234b may be between about 1E20 atoms/cm³ and 6E 21 atoms/cm³, germanium concentration of the epitaxial layer 234c is greater than germanium concentration of the epitaxial layer 234b and is about 30% to about 60%. The third epitaxial process of the epitaxial layer 234c take places from both the exposed sidewalls of the portion 234b2 and the exposed top surface of the portion 234b1. For example, the epitaxial layer 234c includes a portion 234cl epitaxially grown from the exposed top surface of the 234b1 and a portion 234c2 epitaxially grown from the exposed sidewalls of the portion 234b2. The portion 234cl may be formed in a bottom-up approach such to reduce incidences of dislocations. Upon completion of the third epitaxial process, the portion 234cl and the portion 234c2 merge together. The boundary of the portion 234c2 is represented by the dashed rectangles, and there is no physical interface between the portion 234c1 and 234c2. Since a growth rate from (100) direction is greater than a growth rate from (110) direction and (111) direction, upon completion of the epitaxial growth, a thickness of the portion 234cl is greater than a thickness of the portion 234c2. In an embodiment, a thickness of the portion of the 234c2 in the trench 232 is about 1 nm to about 2 nm. It is noted that, upon completion of the third epitaxial process, the trench 232 is fully filled. In an embodiment, the epitaxial layer 234c has a higher dopant concentration than the epitaxial layers 234a-234b, a higher germanium concentration than the epitaxial layers 234a-234b and a larger volume than each of the epitaxial layers 234a-234b and 234e. Percentage of the epitaxial layer 234c in the source/drain feature 234 plays an important role (e.g., strain, parasitic resistance) regarding the performance of the p-type transistor. In comparison with some existing source/drain features which include a continuous lightly doped epitaxial layer (e.g., similar to the composition of the epitaxial layer 234b) that extend along sidewalls of the inner spacers 226, the volume of the epitaxial layer 234b of the present disclosure is reduced, and the volume of the epitaxial layer 234c of the present disclosure is increased. Thus, the strain to the channel layers induced by the source/drain feature 234 may be increased, thereby increasing the carrier mobility.

The fourth epitaxial process, such as VPE, UHV-CVD, MBE, and/or other suitable processes, is performed to form the epitaxial layer 234d on the epitaxial layer 234c. The fourth epitaxial growth process may use gaseous and/or liquid precursors (e.g., silane, dichloride silane, disilane, diiodosilane, iodosilane, disilane, germane, digermane, diiodogermane, iodogermane, tetrachloride), which interact with the composition of the epitaxial layer 234c. The epitaxial layer 234d may include boron-doped silicon germanium, gallium-doped silicon germanium or other suitable material and may be in-situ doped during the epitaxial process by introducing a p-type dopant, such as boron or gallium, or ex-situ doped using a junction implant process. In an embodiment, the epitaxial layer 234d is formed of boron-doped silicon germanium. Boron concentration of the epitaxial layer 234d may be between about 1E 20 atoms/cm³ and 6E 21 atoms/cm³. Germanium concentration of the epitaxial layer 234d is greater than germanium concentration of the epitaxial layer 234b and is about 30% to about 60%. After forming the lower source/drain features 234, the blocking layer 228 may be selectively removed.

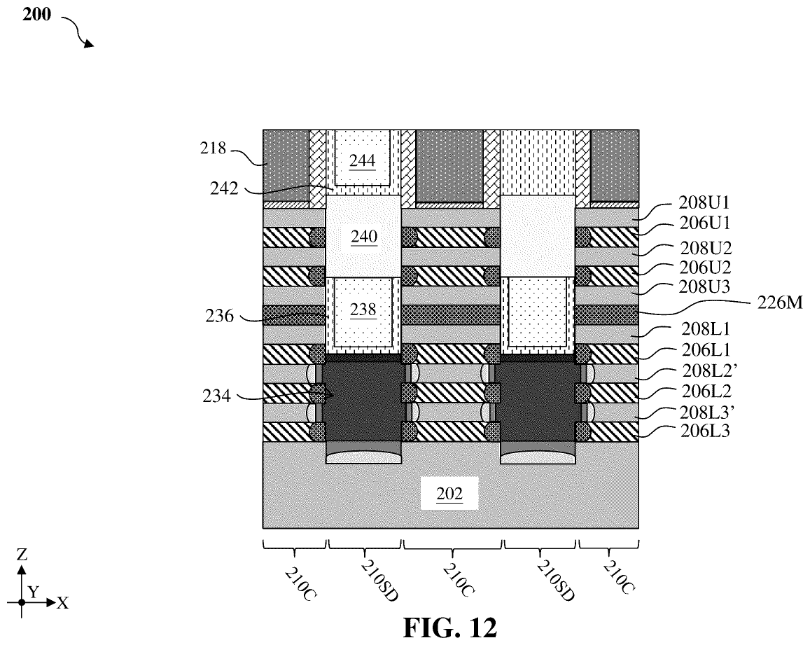

Referring to FIGS. 2 and 12, method 100 includes a block 114 where a bottom contact etch stop layer (CESL) 236 and a bottom interlayer dielectric (ILD) layer 238 are formed. The bottom CESL 236 may include silicon nitride, silicon oxynitride, and/or other materials and may be formed by CVD, ALD, plasma-enhanced chemical vapor deposition (PECVD) process and/or other suitable deposition or oxidation processes. In an embodiment, the bottom CESL 236 includes silicon nitride. The bottom ILD layer 238 may include materials such as tetraethylorthosilicate (TEOS) oxide, un-doped silicate glass, or doped silicon oxide such as borophosphosilicate glass (B PSG), fused silica glass (FSG), phosphosilicate glass (PSG), boron doped silicon glass (BSG), and/or other suitable dielectric materials. In some embodiments, the bottom CESL 236 is first conformally deposited on the intermediate structure 200 and the bottom ILD layer 238 is deposited over the bottom CESL 236 by spin-on coating, flowable CVD (FCVD), CVD, or other suitable deposition technique. The bottom CESL 236 and the bottom ILD layer 238 may be etched back to exposed sidewalls of the upper channel layers 208U 1-208U 2, as illustrated.

Still referring to FIGS. 2 and 12, method 100 includes a block 116 where upper source/drain features 240 are formed to couple to the upper channel layers 208U 1-208U 2. The upper source/drain features 240 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U 1 and 208U 2) of the top portion 204T of the superlattice structure 204. The epitaxial growth of upper source/drain features 240 may take place from the exposed sidewalls of the top channel layers 208U1 and 208U 2. The deposited upper source/drain features 240 are in physical contact with (or adjoining) the channel layers of the top portion 204T of the superlattice structure 204. Depending on the design, the upper source/drain features 240 may be n-type or p-type. In the depicted embodiments, the upper source/drain features 240 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. In the present disclosure, since the lower portion of the source/drain opening 224 is enlarged, the lower source/drain feature 234 may span a width (e.g., W0+2*W1) greater than a width (e.g., W1) of the upper source/drain feature 240.

Referring to FIGS. 2 and 12-13, method 100 includes a block 118 where the dummy gate stacks 214 and the sacrificial layers 206 of the superlattice structure 204 are replaced with gate structures 254. With reference to FIG. 12, a top CESL 242 and a top ILD layer 244 are deposited over the upper source/drain features 240. The top CESL 242 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 242 is first conformally deposited on the intermediate structure 200 and the top ILD layer 244 is then deposited over the top CESL 242 by spin-on coating, FCVD, CVD, or other suitable deposition technique. The top IL D layer 244 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 244, the intermediate structure 200 may be annealed to improve integrity of the top IL D layer 244. To remove excess materials and to expose top surfaces of the dummy gate electrode layers 218, a planarization process, such a chemical mechanical polishing (CM P) process may be performed.

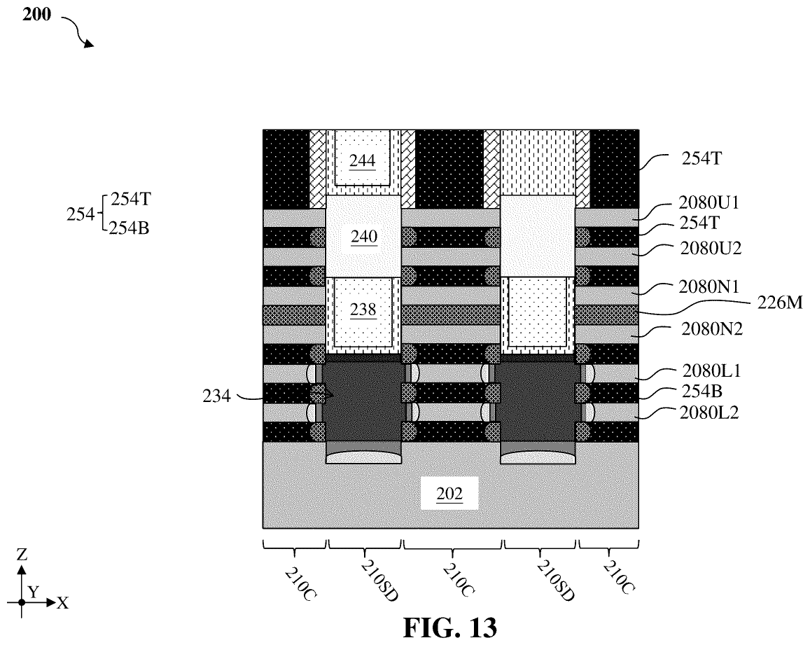

With reference to FIG. 13, operations at block 118 may also include removal of the dummy gate stacks 214, release of the channel layers 208 as channel members (including upper channel members 2080U1-2080U2, and lower channel members 2080L 1-2080L 2) and nanostructures (including the nanostructures 2080N 1 and 2080N 2). The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including the upper channel members 2080U1-2080U2, the lower channel members 2080L1-2080L 2) and nanostructures (including the nanostructures 2080N1 and 2080N2). The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In embodiments represented by FIG. 13, the nanostructures 2080N1 and 2080N2 are in contact with the middle dielectric layer 226M. Since the channel layers 208L 2-208L3 are laterally recessed at block 110, a width of each of the lower channel members 2080L 1-2080L2 may be less than a width of each of the upper channel members 2080U 1-2080U 2 and the nanostructures 2080N 1 and 2080N 2.

With the release of the channel members, a gate structure 254 is deposited to wrap around each of the channel members (e.g., channel members 2080U1, 2080U 2, 2080L1, 2080L2). While not explicitly shown in the figures, the gate structure 254 includes an interfacial layer to interface the channel members, a gate dielectric layer over the interfacial layer, and a p-type work function layer and/or an n-type work function layer over the gate dielectric layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-K dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material.

After the deposition of the gate dielectric layer, the n-type work function layer and the p-type work function layer may be sequentially deposited. The p-type work function layer and the n-type work function layer may include a single layer or alternatively a multi-layer structure, such as various combinations of a metal layer with a selected work function to enhance the device performance (work function metal layer). By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. The gate structure 254 may also include a liner layer, a wetting layer, an adhesion layer, a metal alloy, or a metal silicide. The gate structure 254 may also include a metal fill to reduce contact resistance. In some instance, the metal fill includes tungsten (W).

In some embodiments, the gate structure 254 may be a common gate structure that wraps around both the upper channel members 2080U 1-2080U2 and the lower channel members 2080L 1-2080L2. In some other embodiments depicted in the drawings, the gate structure 254 includes a bottom gate portion 254B wrapping around the lower channel members 2080L 1-2080L 2 and a top gate portion 254T wrapping around the upper channel members 2080U1-2080U2. The bottom gate portion 254B and the top gate portion 254T have different work function layers. For example, the top gate portion 254T may include n-type work function layer(s) and the bottom gate portion 254B may include p-type work function layer(s). When the gate structure 254 includes a bottom gate portion 254B and a top gate portion 254T, the two gate portions may be electrically isolated from each other.

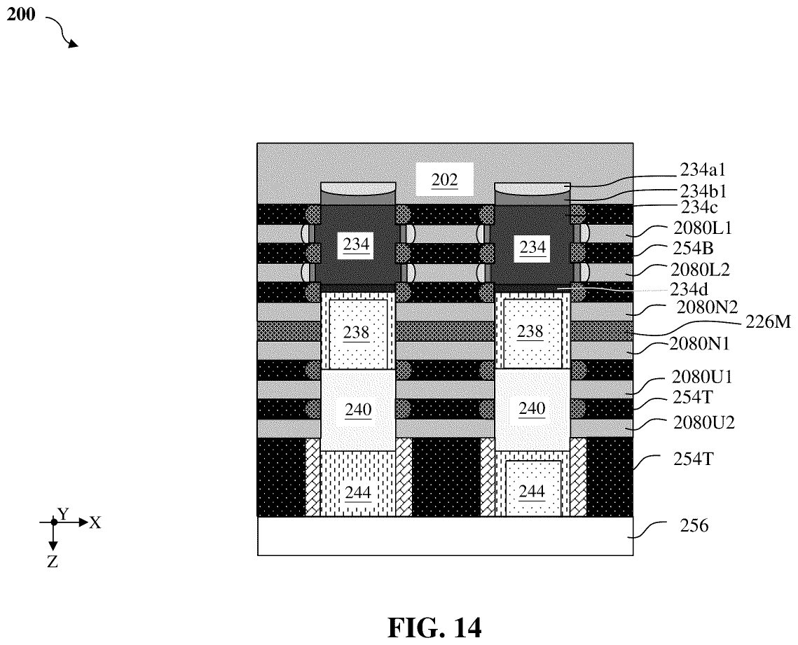

Referring to FIGS. 2 and 14, method 100 includes a block 120 where the intermediate structure 200 is flipped over. After forming the gate structures 254, a multi-layer interconnect structure 256 may be formed over the front side of the transistors. The multi-layer interconnect structure 256 may include a number of conductive features (e.g., metal lines and/or vias) configured to interconnect various components of the transistors with additional features. The conductive features of the multi-layer interconnect structure 256 may be disposed in and/or separated by intermetal dielectric (IM D) layers. The conductive features of the multi-layer interconnect structure 256 may include metal lines/contacts formed on or over the frontside source/drain vias or the gate vias. Each conductive feature of the multi-layer interconnect structure 256 may be formed of metal, such as aluminum, tungsten, ruthenium, or copper. Each IM D layer may include a low-k dielectric material, silicon oxide, other suitable dielectric materials, or combinations thereof, and may be formed by spin-on-glass, flowable CVD (FCVD), other suitable methods, or combinations thereof. After forming the multi-layer interconnect structure 256 over the front side of the substrate 202, a carrier substrate (not shown) may be bonded to the multi-layer interconnect structure 256, and the intermediate structure 200 is then flipped over, as illustrated by FIG. 14. In some embodiments, a thinning process may be performed to thin the substrate 202 from its backside to reduce a total thickness of the intermediate structure 200. The thinning process may include a mechanical grinding process and/or a chemical thinning process. For example, a substantial amount of substrate material may be removed from the substrate 202 during a mechanical grinding process. For ease of description, the positional relationships (e.g., over, below, above, under) of features of the flipped-over intermediate structure 200 will be described in accordance with the figures. For example, as shown in FIG. 14, after the intermediate structure 200 is flipped over, the substrate 202 is disposed over the channel members 2080U 1-2080U 2.

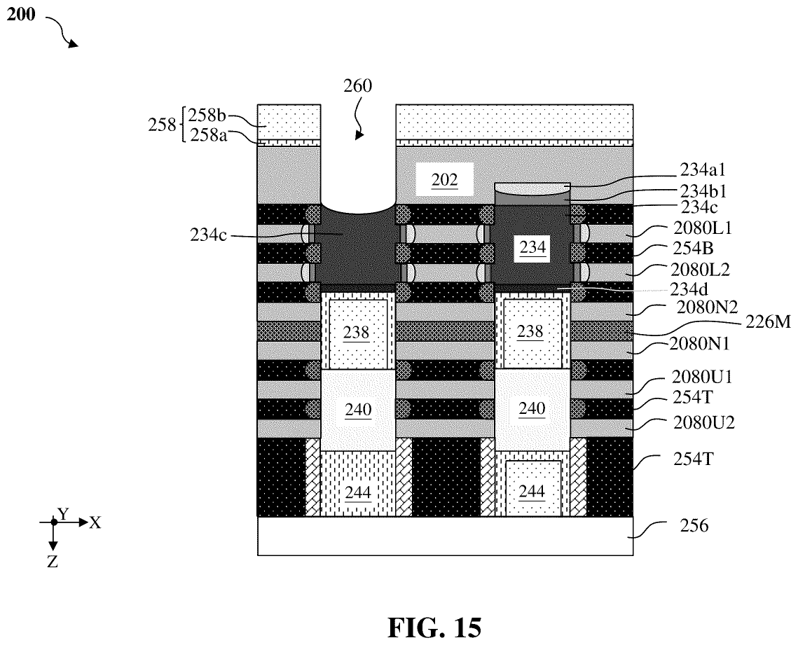

Referring to FIGS. 2 and 15, method 100 includes a block 122 where a backside opening 260 is formed to extend through the substrate 202 to expose the epitaxial layer 234c. A dielectric structure 258 is formed over a back side of the substrate 202. In the present embodiment, to provide an end point for a subsequent planarization process, the dielectric structure 258 includes a first layer 258a and a second layer 258b having a material composition different than the first layer 258a. In an embodiment, the first layer 258a includes a nitride layer (e.g., silicon nitride), and the second layer 258b includes an oxide layer (e.g., silicon oxide). Then, a masking element may be formed over the backside of the dielectric structure 258. The masking element may include an opening directly over the backside of the source/drain feature 234. While using the masking element as an etch mask, an etching process is performed to form pattern the dielectric structure 258. The masking element may be selectively removed after patterning the dielectric structure 258. An etching process is then performed to form a backside opening 260 extending through the substrate 202 and into the source/drain feature 234. The etching process removes a portion of the substrate 202, a part or an entirety of the portion 234al of the epitaxial layer 234a, and a part or an entirety of the portion 234b1 of the epitaxial layer 234b, and a portion of the epitaxial layer 234c. The partially etched source/drain feature 234 is referred to as the source/drain feature 234′. In this illustrated embodiment, in comparison with the source/drain feature 234, the source/drain feature 234′ does not include the portion 234al and the portion 234b1 and includes a partially recessed epitaxial layer 234c.

As described above, the epitaxial layer 234c has a higher germanium concentration and a higher dopant concentration than those of the epitaxial layer 234a and epitaxial layer 234b. Forming the backside opening 260 exposing the epitaxial layer 234c can help reduce contact resistance between the source/drain feature 234′ and the silicide layer 264 that will be formed in the backside opening 260. In comparison with some other source/drain features which include a continuous lightly doped epitaxial layer that extend along sidewalls of the inner spacers 226, the profile of the epitaxial layer 234b of this present disclosure is controlled, the space for forming the epitaxial layer 234c is thus enlarged. For example, a vertical distance between the epitaxial layer 234c and the substrate 202 is reduced, and a lateral distance between the epitaxial layer 234c and the channel members disposed directly under the gate structure 254B is reduced. In comparison with those existing technologies, the forming of the backside opening 260 that exposes the epitaxial layer 234c will remove a reduced volume of the source/drain feature 234. Therefore, upon formation of the backside opening 260, the volume of the resulted source/drain feature 234′ in the present disclosure is greater than the volume of the resulted source/drain feature in those existing technologies.

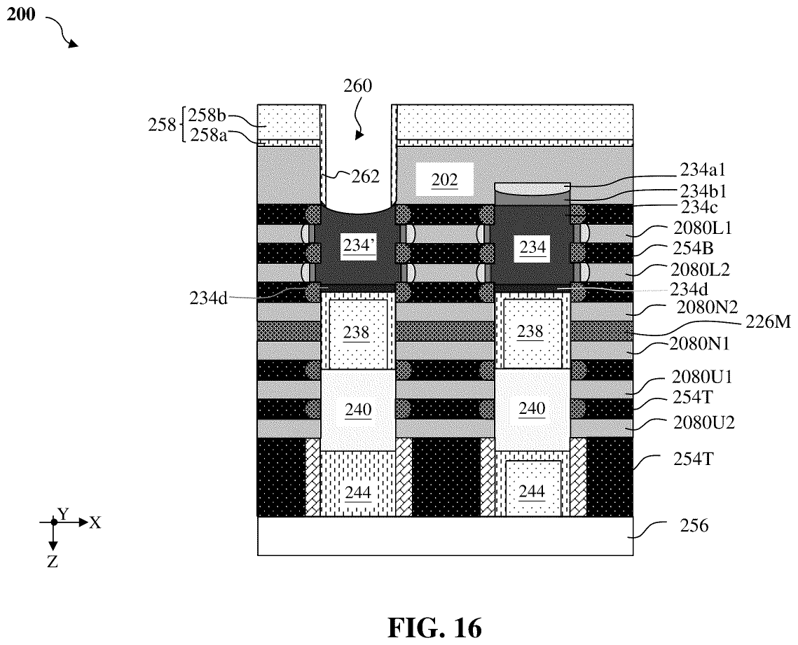

Referring to FIGS. 2 and 16-17, method 100 includes a block 124 where a backside via 266 is formed in the backside opening 260. With reference to FIG. 16, a dielectric liner 262 is formed in the backside opening 260. In an exemplary process, a dielectric barrier layer is conformally deposited over the backside of the substrate 202, including in the backside opening 260. The dielectric barrier layer is then etched back to only cover sidewalls of the backside opening 260 and expose the bottom surface of the epitaxial layer 234c of the source/drain feature 234′. The etched back dielectric barrier layer forms the dielectric liner 262 in the backside opening 260. In some embodiments, the dielectric liner 262 may include silicon nitride or other suitable materials. The dielectric liner 262 may be in contact with the bottommost inner spacer 226.

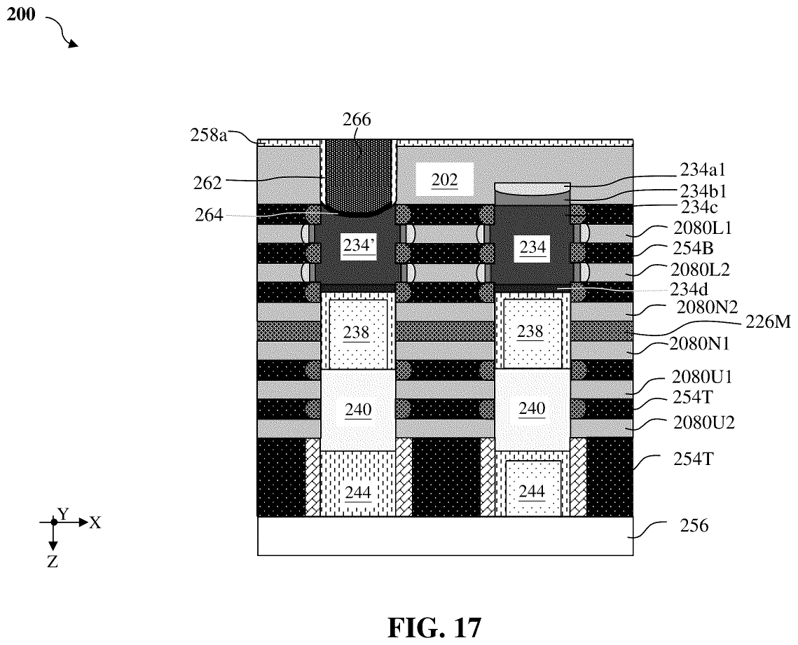

With reference to FIG. 17, after forming the dielectric liner 262, a silicide layer 264 is formed on the exposed surface of the source/drain feature 234′ to reduce a contact resistance between the source/drain feature 234′ and the backside via 266. To form the silicide layer 264, a metal layer (not explicitly shown) is deposited over the backside of the substrate 202 and an anneal process is performed to bring about silicidation reaction between the metal layer and the epitaxial layer 234c of source/drain feature 234′. Suitable metal layer may include titanium, tantalum, nickel, cobalt, or tungsten. Excessive metal layer that does not form the silicide layer 264 may be removed. After forming the silicide layer 264, a backside via 266 is formed. In an exemplary process, the formation of the backside via 266 may include depositing a conductive layer (e.g., aluminum, rhodium, ruthenium, copper, iridium, or tungsten) over the bottom surface of the substrate 202 to fill the opening 260 and performing a planarization process (e.g., chemical mechanical polish (CMP) process) to remove excess materials. The planarization process stops on the bottom surface of the first layer 258a. The backside via 266 is electrically coupled to the source/drain feature 234′ by way of the silicide layer 264. Further processes may be performed to the intermediate structure 200 to form a final structure.

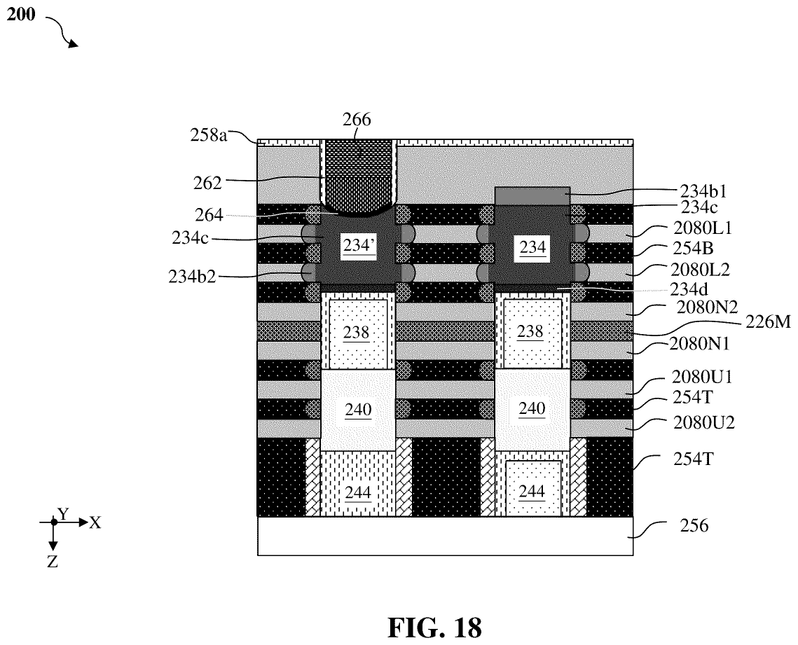

In the above embodiments described with reference to FIGS. 10-17, the source/drain feature 234 and the source/drain feature 234′ include the epitaxial layer 234a. In another alternative embodiment represented by FIG. 18, the epitaxial layer 234a may be omitted. It is noted that, the space for forming the epitaxial layer 234a will be occupied by the epitaxial layer 234b. The epitaxial layer 234c still extends into the trenches 232 (shown in FIG. 9), as illustrated in FIG. 18.

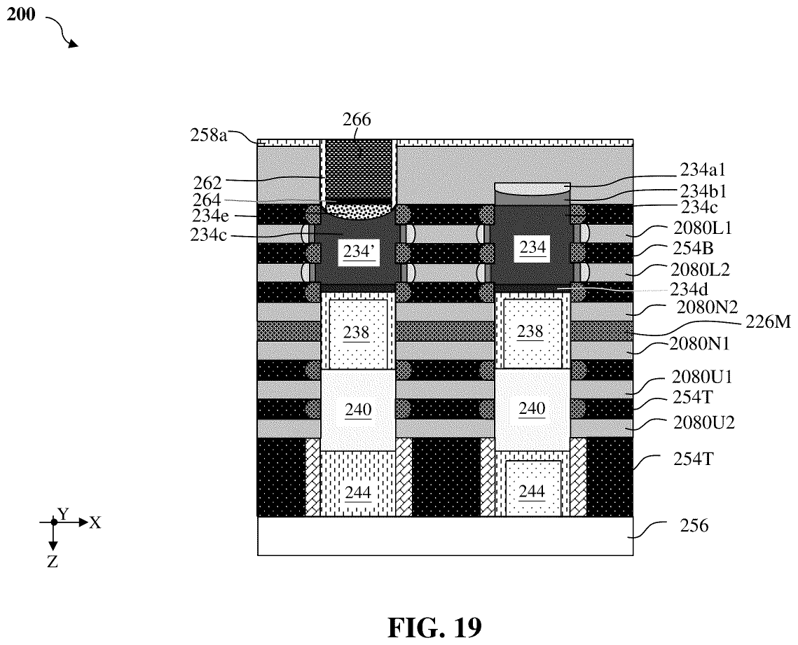

In the above embodiments described with reference to FIGS. 15-17, after forming the dielectric liner 262, the silicide layer 264 and the backside via 266 are formed in the backside opening 260. In another alternative embodiment represented by FIG. 19, to further reduce the resistance (e.g., contact resistance and parasitic resistance of the source/drain feature 234′), after forming the dielectric liner 262 and before forming the silicide layer 264, an epitaxial layer 234e is formed in the backside opening 260. To form the epitaxial layer 234e, a fifth epitaxial process, such as VPE, UHV-CVD, MBE, and/or other suitable processes, is performed. The fifth epitaxial growth process may use gaseous and/or liquid precursors (e.g., silane, dichloride silane, disilane, diiodosilane, iodosilane, disilane, germane, digermane, diiodogermane, iodogermane, tetrachloride germane, diborane, boron trichloride, HCl), which interact with the composition of the epitaxial layer 234c. The epitaxial layer 234e may include boron-doped silicon germanium, gallium-doped silicon germanium or other suitable material and may be in-situ doped during the epitaxial process by introducing a p-type dopant, such as boron or gallium, or ex-situ doped using a junction implant process. In an embodiment, the epitaxial layer 234e is formed of boron-doped silicon germanium. In an embodiment, germanium concentration of the epitaxial layer 234e is about 40% to about 95% and is greater than the germanium concentration of the epitaxial layer 234c, and dopant (e.g., boron) concentration of the epitaxial layer 234e may be between about 1E 20 atoms/cm³ and 6E 21 atoms/cm³ and greater than dopant concentration of the epitaxial layer 234c. Forming the epitaxial layer 234e may increase the volume of the source/drain feature 234′ and increase dopant concentration, thereby reducing parasitic resistance and increasing strain to enhance carrier mobility. The source/drain feature 234′ repressed by FIG. 19 may either include the epitaxial layer 234a or be free of the epitaxial layer 234a.

FIG. 20 illustrates a flow chart of another method 300 for forming a semiconductor device 400 (e.g., GA A transistor), according to one or more aspects of the present disclosure. [[Dear inventor, based on your slides, I added a p-type DOI GAA embodiment (FIGS. 20-30). Please advise whether this embodiment is applicable to form n-type source/drain features in an n-type GAA as well. Thanks!]] FIGS. 21-30 illustrate fragmentary cross-sectional views of the semiconductor device 400 during various fabrication stages in the method 300 of FIG. 20, according to one or more aspects of the present disclosure.

Referring to FIGS. 20 and 21, method 100 includes a block 302 where a fin-shaped structure 410 is formed over a substrate 402. The substrate 402 may be similar to the substrate 202, and repeated description is omitted for reason of simplicity. The fin-shaped structure 410 may be formed from a top portion 402t of the substrate 402 and a vertical stack 407 (shown in FIG. 3) of alternating sacrificial layers 406 and channel layers 408 using a combination of lithography and etch steps. In an embodiment, the sacrificial layers 406 may be similar to the sacrificial layers 206, the channel layers 408 may be similar to the channel layers 208, and the vertical stack 407 may be similar to the bottom portion 204B. In some examples, the fin-shaped structure 410 may include a total of three to ten pairs of alternating sacrificial layers 406 and channel layers 408; of course, other configurations may also be applicable depending upon specific design requirements.

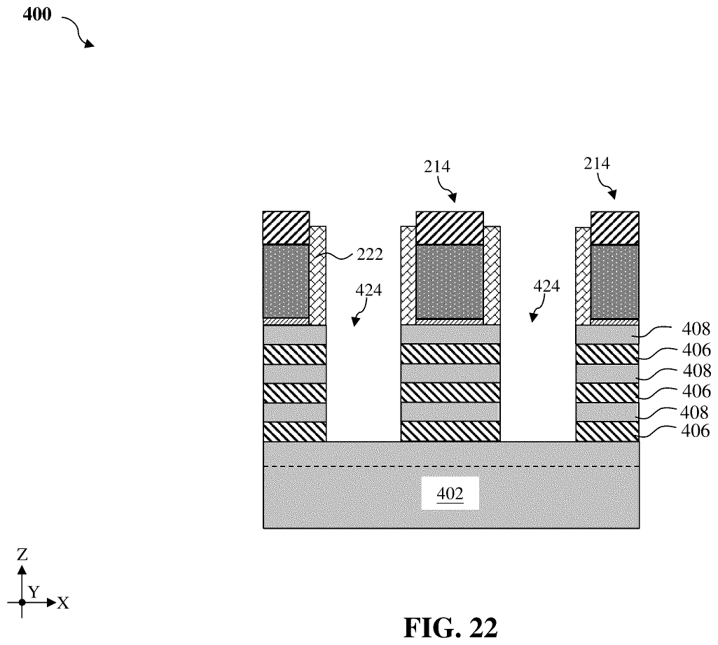

Referring to FIGS. 20 and 22, method 100 includes a block 304 where dummy gate stacks 214 are formed over channel regions of the fin-shaped structure 410. The formation of the dummy gate stacks 214 has been described above and repeated description is omitted for reason of simplicity.

Still referring to FIGS. 20 and 22, method 100 includes a block 306 where source/drain openings 424 are formed. The formation of the source/drain openings 424 is similar to the formation of the source/drain openings 224, and one difference between the source/drain openings 224 and the source/drain openings 424 includes that, the source/drain openings 224 extend through the fin-shaped structure 210, while the source/drain openings 424 extend through the fin-shaped structure 410.

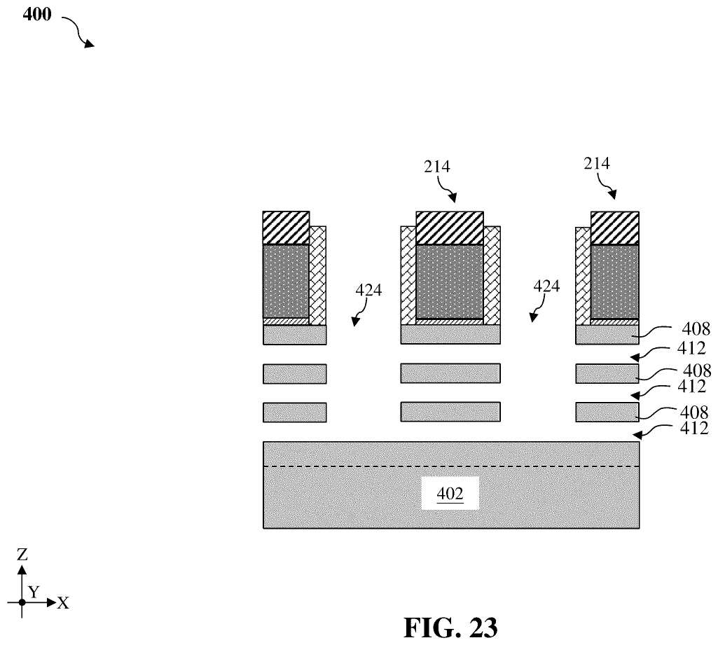

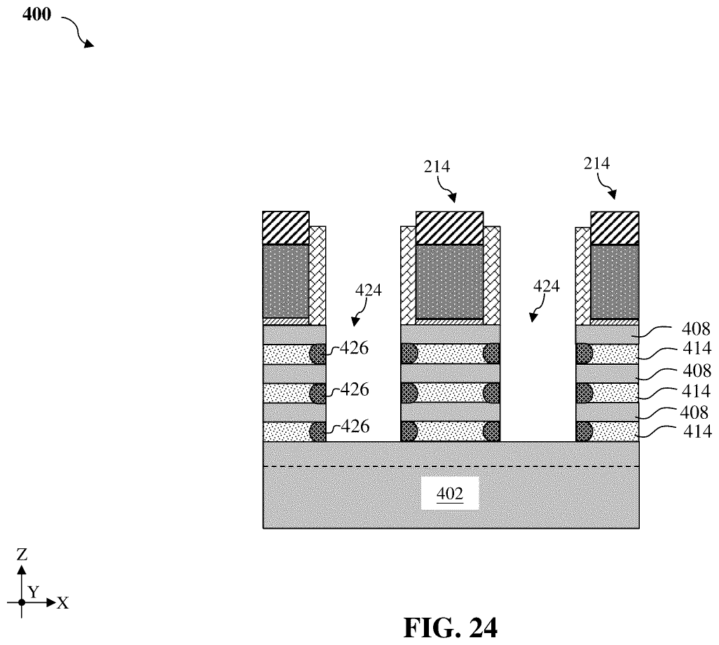

Referring to FIGS. 20 and 23-24, method 100 includes a block 308 where the sacrificial layers 406 are replaced with dummy layers 414. With reference to FIG. 23, after the formation of the source/drain openings 424, the sacrificial layers 406 interleaving the channel layers 408 in the channel region are selectively removed. Depending on the design, the channel layers 408 may take form of nanowires, nanosheets, or other nanostructures. The selective removal of the sacrificial layers 406 forms spaces 412 between and around adjacent channel layers 408. The selective removal of the sacrificial layers 406 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). With reference to FIG. 24, after the selective removal of the sacrificial layers 406, in an example process, a dielectric material layer is deposited around the channel layers 408 and over the source/drain openings 424. The dielectric material layer fills the space 412 among the channel layers 408 and covers end sidewalls of the channel layers 408. After the deposition of the dielectric material layer, an etching process is performed to selectively etch the dielectric material layer, thereby forming the dummy layers 414 interleaved by the channel layers 408. The dielectric material layer may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or atomic layer deposition (ALD) or other suitable methods. In an embodiment, the dielectric material layer includes silicon oxide. In an embodiment, the etching process further forms inner spacer recesses exposing sidewalls of the dummy layers 414. In some embodiments, the sacrificial layers 206 described with reference to method 100 may also be replaced by layers similar to the dummy layers 414 before the forming of inner spacers 226.

Referring to FIGS. 20 and 24, method 100 includes a block 310 where inner spacers 426 are formed. The formation of the inner spacers 426 may be similar to the formation of the inner spacers 226, and repeated description is omitted for reason of simplicity. It is noted that, in this embodiment, the inner spacers 426 adjoin the dummy layers 414.

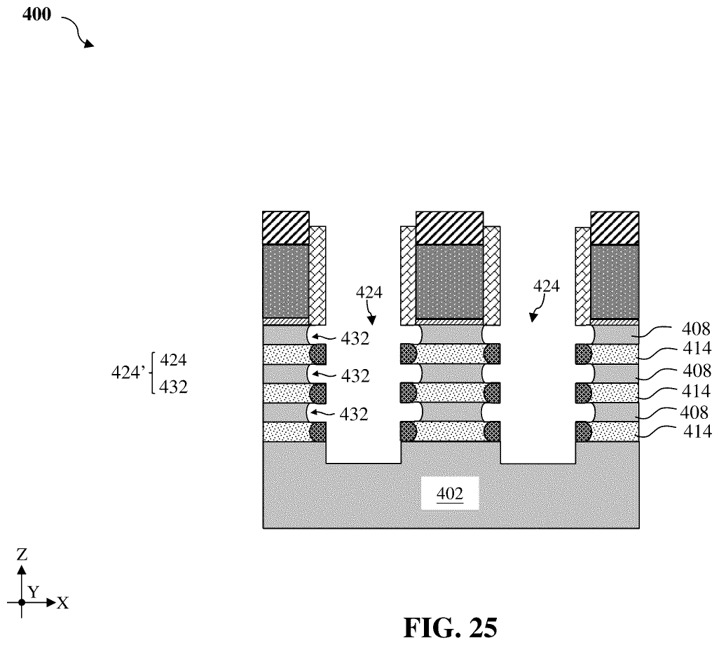

Referring to FIGS. 20 and 25, method 100 includes a block 312 where the channel layers 408 are laterally recessed to form trenches 432. Operations performed at block 312 may be similar to those of the block 110, and the resulted trenches 432 are similar to the trenches 232, and repeated description is omitted for reason of simplicity. The source/drain openings 424 and the trenches 432 may be collectively referred to as source/drain openings 424′. The source/drain openings 424′ may be similar to the lower portion of the source/drain openings 224′.

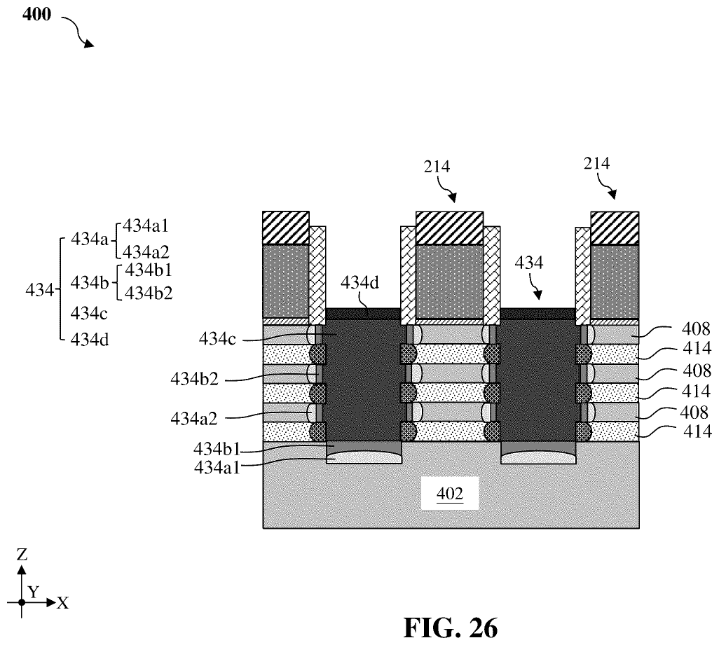

Referring to FIGS. 20 and 26, method 100 includes a block 314 where source/drain features 434 are formed in the source/drain openings 424′. The source/drain features 434 are similar to the source/drain features 234. For example, in an embodiment, the source/drain feature 434 is a p-type source/drain feature and includes multiple doped epitaxial layers, such as epitaxial layers 434a, 434b, 434c, and 434d. The epitaxial layers 434a, 434b, 434c, and 434d are similar to the epitaxial layers 234a, 234b, 234c, and 234d, respectively, and may be formed by the first epitaxial process, the second epitaxial process, the third epitaxial process, and the fourth epitaxial process, respectively. In an embodiment, a top surface of the epitaxial layer 434d is above a topmost channel layer 408 of the channel layers 408.

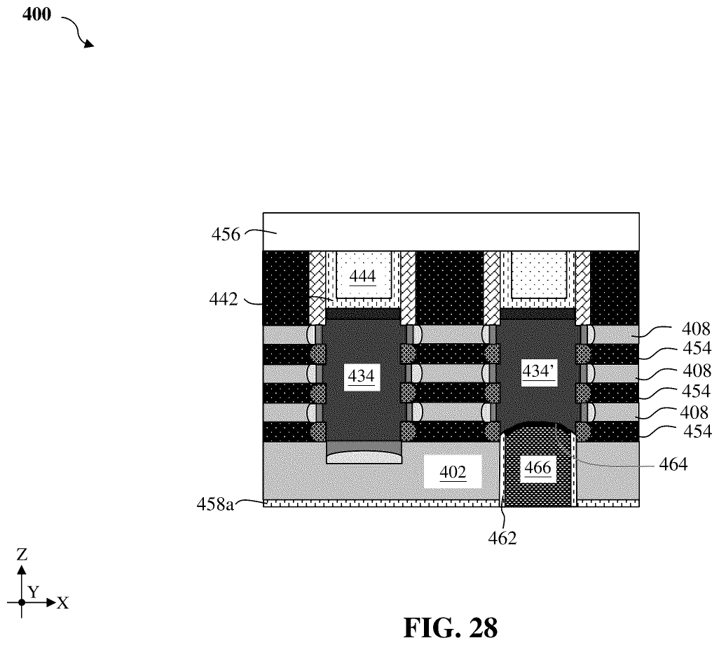

Referring to FIGS. 20 and 27-28, method 100 includes a block 316 where the dummy gate stack 214 and the dummy layers 414 are replaced by a gate structure 454. After forming the source/drain features 434, a CESL 442 and a ILD layer 444 are deposited over the source/drain features 434. The CESL 442 and the ILD layer 444 are similar to the top CESL 242 and top ILD layer 244, respectively. With reference to FIG. 28, operations at block 316 may also include selectively removing the dummy gate stacks 214 to form gate trenches. The etching process for removing the dummy gate stacks 214 may include any suitable process, such as a dry etching process, a wet etching process, or combinations thereof, and is configured to selectively remove the dummy gate stacks 214. After removing the dummy gate stacks 214, the dummy layers 414 are selectively removed to form gate openings. The selective removal of the dummy layers 414 may be implemented by a selective dry etch, a selective wet etch, or other selective etching process. An example selective wet etch process may include use of diluted hydrofluoric acid (DHF) or a mixture of hydrofluoric acid (HF) and, ammonium fluoride (NH4F). An example selective dry etch process may include use of anhydrous hydrogen fluoride (HF) vapor, trifluoromethane (CHF3), nitrogen trifluoride (NF3), hydrogen (H2), ammonia (NH3), carbon tetrafluoride (CF4), sulfur hexafluoride (SF6), or a combination thereof. In some embodiments, the selective wet etching includes an APM etch (e.g., ammonia hydroxide-hydrogen peroxide-water mixture). A gate structure 454 is then formed in the gate openings and the gate trench to wrap around the channel layers 408. The gate structure 454 may be similar to the lower portion 254B of the gate structure 254, and repeated description is omitted for reason of simplicity.

Referring to FIGS. 20 and 28, method 100 includes a block 318 where a backside via 466 is formed. Operations at block 318 may include operations at block 120, 122, and 124 described above, and repeated description is omitted for reason of simplicity. Upon completion of the operations at block 318, the semiconductor device 400 includes a multi-layer interconnect structure 456 over the gate structures 454. The multi-layer interconnect structure 456 may be similar to the multi-layer interconnect structure 256. The semiconductor device 400 also includes a dielectric layer 458a similar to the first layer 258a, a dielectric liner 462 similar to the dielectric liner 262, a silicide layer 464 similar to the silicide layer 264, and a backside via 466 similar to the backside via 266. The formation of the backside via 466 removes a portion (e.g., the portion 434a1 of the epitaxial layer 434a, the portion 434b1 of the epitaxial layer 434b, and a portion of the epitaxial layer 434c) of the source/drain feature 434. The partially etched source/drain feature 434 may be referred to as the source/drain feature 434′. The silicide layer 464 is in contact with the epitaxial layer 434c of the source/drain feature 434′.

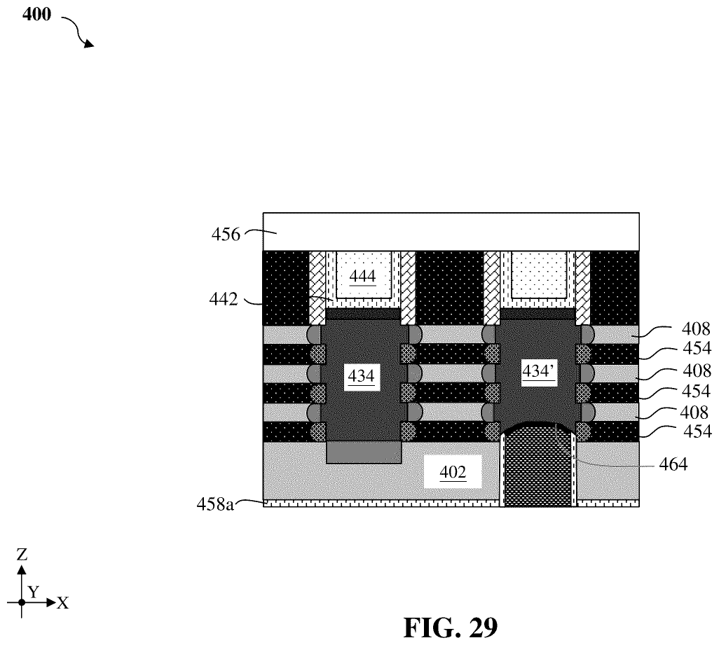

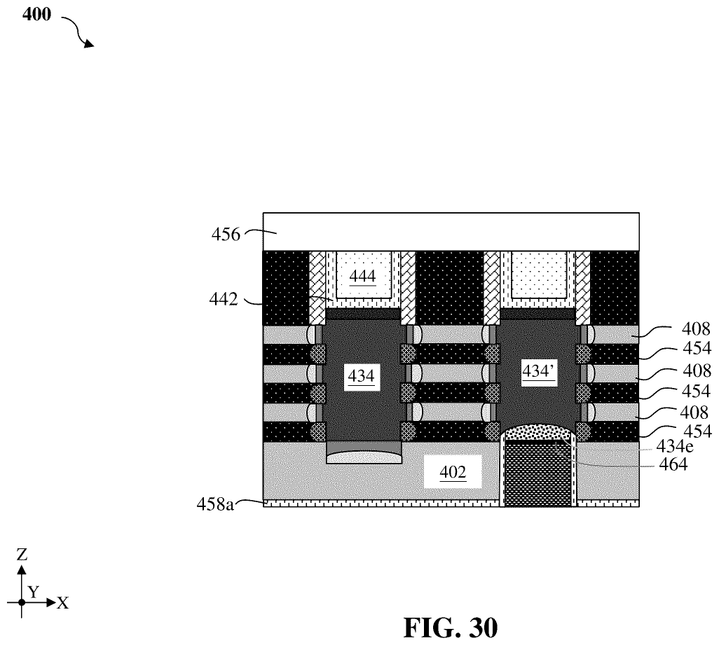

In an alternative embodiment illustrated by FIG. 29, as similar to the embodiment described with reference to FIG. 18, the source/drain feature 434 and the source/drain feature 434′ may be free of the epitaxial layer 434a. In another alternative embodiment illustrated by FIG. 30, as similar to the embodiment described with reference to FIG. 19, the source/drain feature 434′ may further include an epitaxial layer 434e similar to the epitaxial layer 234e. The source/drain feature 434 and the source/drain feature 434′ repressed by FIG. 30 may either include the epitaxial layer 434a as represented by FIG. 30 or do not include the epitaxial layer 434a.

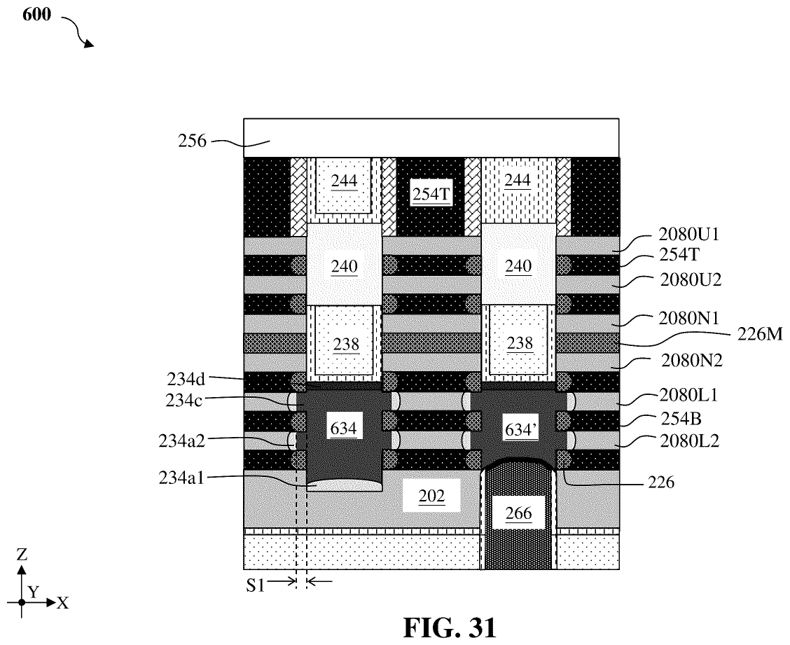

In the above embodiments described with reference to FIG. 10, upon completion of the forming of the source/drain feature 234, the source/drain feature 234 includes the epitaxial layer 234b disposed between the epitaxial layer 234a and the epitaxial layer 234c. In some alternative embodiments, the source/drain feature may be free of the epitaxial layer 234b. Each of FIGS. 31, 32, and 33 depicts a fragmentary cross-sectional view of a semiconductor device that does not include the epitaxial layer 234b. With reference to FIG. 31, a semiconductor device 600 is illustrated. The semiconductor device 600 is similar to the semiconductor device 200 represented by FIG. 17, and the differences between these two semiconductor devices include that, the semiconductor device 600 includes a lower source/drain feature 634 and a lower source/drain feature 634′ that are free of the epitaxial layer 234b. For example, after performing operations at blocks 102-110 of method 100, the epitaxial layers 234a, 234c, and 234d are formed in a sequential order to form the lower source/drain feature 634. More specifically, a first epitaxial process is performed to form the epitaxial layer 234a, a second epitaxial process is performed to form the epitaxial layer 234c after forming the epitaxial layer 234a, a third epitaxial process is performed to form the epitaxial layer 234d after forming the epitaxial layer 234c. Details of the epitaxial layers 234a, 234c, and 234d have been described above, and repeated description is omitted for reason of simplicity. In this illustrated embodiment, the portion 234a2 of the first epitaxial layer 234 partially fills the trench 232 (shown in FIG. 9), and the epitaxial layer 234c fills a remaining portion of the trench 232 and is thus vertically overlapped with the inner spacer 226. A width S1 of the overlapped portion of the epitaxial layer 234c may be between about 1 nm and about 5 nm. After forming the lower source/drain feature 634, operations at blocks 114-124 of method 100 may be performed, thereby forming the semiconductor device 600 represented by FIG. 31. The difference between the source/drain feature 634′ and the source/drain feature 234′ is the same as the difference between the source/drain feature 634 and the source/drain feature 234, and repeated description is omitted for reason of simplicity.

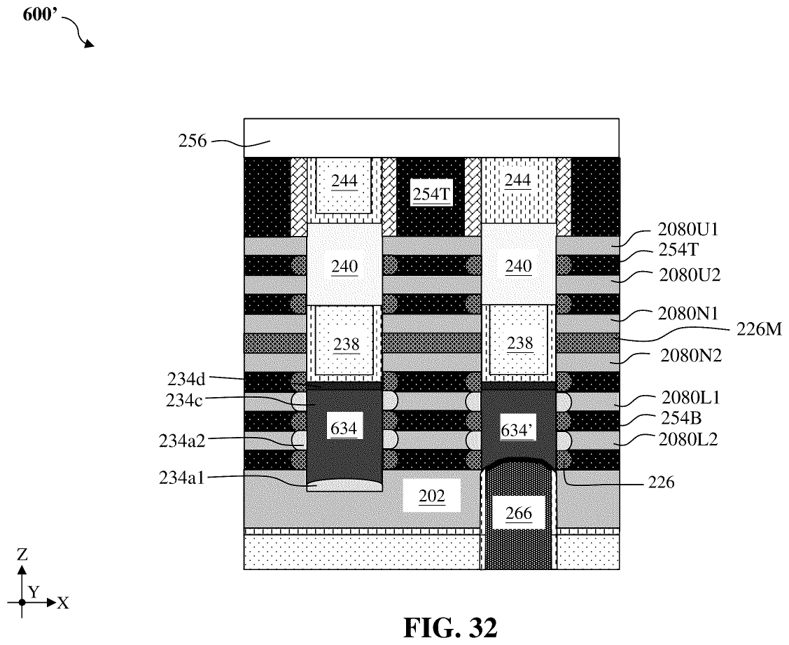

FIG. 32 depicts a fragmentary cross-sectional view of a semiconductor device 600′. The semiconductor device 600′ is similar to the semiconductor device 600 represented by FIG. 31. The main differences between these two semiconductor devices include that, the portion 234a2 of the first epitaxial layer 234 substantially fully fills the trench 232 (shown in FIG. 9), and the epitaxial layer 234c does not vertically overlap the inner spacer 226. In an embodiment, an interface between the epitaxial layer 234c and the portion 234a2 of the epitaxial layer 234 aligns with a sidewall surface of the inner spacer 226 along the Z direction.

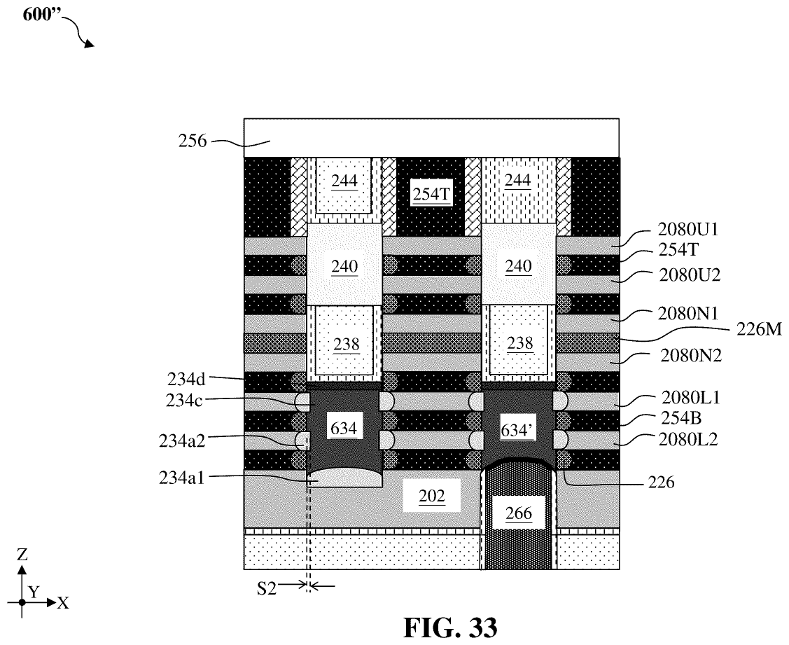

FIG. 33 depicts a fragmentary cross-sectional view of a semiconductor device 600″. The semiconductor device 600″ is similar to the semiconductor device 600 represented by FIG. 31. The main difference between these two semiconductor devices includes that, the first epitaxial layer 234c of the semiconductor device 600″ not only fills the trench 232 (shown in FIG. 9), but also fills a portion of the source/drain opening 224 (shown in FIG. 9) near the trench 232. The epitaxial layer 234c is formed after forming the epitaxial layer 234a. As a result, the portion 234a2 of the epitaxial layer 234a in the semiconductor device 600″ overhangs the inner spacer 226 and extends into the epitaxial layer 234c. A width S2 of the portion of the epitaxial layer 234a extended into the epitaxial layer 234c may be between about 1 nm and about 5 nm.

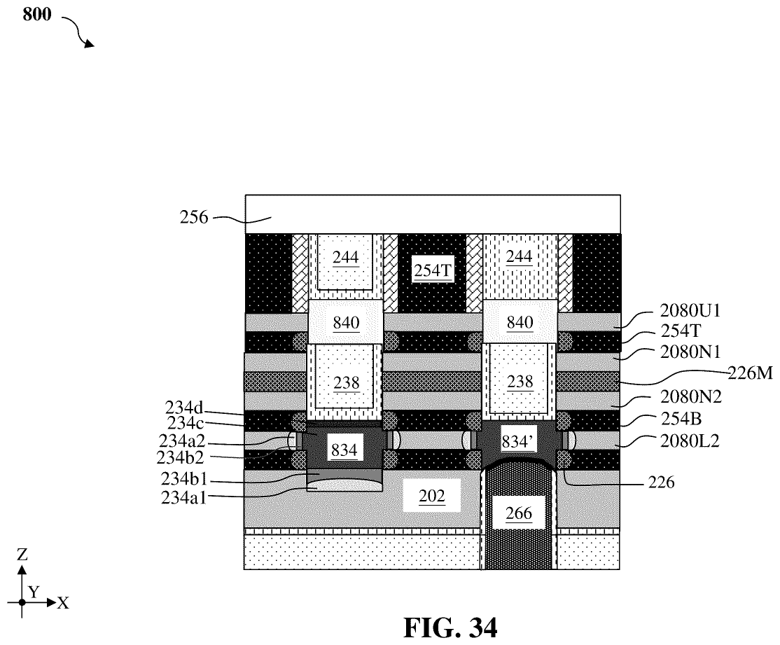

In the above embodiments, source/drain feature of the semiconductor device 200, 400, 600, 600′, 600″ is electrically coupled to two or more nanostructures (e.g., 2080L1 and 2080L2 shown in FIG. 17, 408 shown in FIG. 28). In some other embodiments, the source/drain feature may be electrically coupled to one nanostructure. For example, FIG. 34 depicts a fragmentary cross-sectional view of a semiconductor device 800. The semiconductor device 800 is similar to the semiconductor device 200 described with reference to FIG. 17, and main differences between these two semiconductor devices include that, the semiconductor device 800 includes a bottom source/drain feature 834 coupled to the channel member 2080L 2, a bottom source/drain feature 834′ coupled to the channel member 2080L2 and electrically connected to the backside via 266, and top source/drain features 840 coupled to the channel member 2080U1. It is understood that various different combinations of the above-listed embodiments are within the scope of the present disclosure. For example, the alternative embodiments represented by FIGS. 31-34 are described with reference to CFETs, however, it is understood that the concepts of those alternative embodiments may be applied to the GAA transistors described with reference to FIGS. 20-30. In addition, concepts of those alternative embodiments represented by FIGS. 31-34 may also be applied to the embodiment described with reference to FIG. 19. For example, the semiconductor devices 600, 600′, 600″ may also include the epitaxial layer 234e disposed between the backside via 266 and the source/drain feature 634′.

Although not intended to be limiting, one or more embodiments of the present disclosure provide many benefits to a semiconductor device and the formation thereof. For example, the present disclosure provides a CFET device having a top multi-gate device and a bottom multi-gate device. In an embodiment, the top multi-gate device is a n-type transistor, and the bottom multi-gate device is a p-type transistor. Profiles of different layers of the p-type source/drain features are configured such that the performance (e.g., enhanced carrier mobility, reduced parasitic resistance) of the p-type transistor may be improved.

The present disclosure provides for many different embodiments. Semiconductor structures and methods of fabrication thereof are disclosed herein. In one exemplary aspect, the present disclosure is directed to a method. The method includes forming a semiconductor layer stack over a substrate, the semiconductor layer stack having an upper channel layer over a lower channel layer, performing an etching process to laterally recess the lower channel layer without substantially etching the upper channel layer, forming a first source/drain feature coupled to the recessed lower channel layer, and forming a second source/drain feature coupled to the upper channel layer, the second source/drain feature is disposed over the first source/drain feature.

In some embodiments, the first source/drain feature spans a first width, the second source/drain feature spans a second width less than the first width. In some embodiments, the method may also include forming a first inner spacer under the lower channel layer and a second inner spacer over the lower channel layer, and the laterally recessing of the lower channel layer forms a groove exposing a bottom surface of the second inner spacer and a top surface of the first inner spacer. In some embodiments, the first source/drain feature may include a doped layer having a first portion in the groove and a second portion disposed below the first inner spacer, and the first portion of the doped layer partially fills the groove. In some embodiments, a thickness of the second portion is greater than a thickness of the first portion. In some embodiments, the doped layer is a first doped layer, and the first source/drain feature may also include a second doped layer, the second doped layer extends into the groove, and a topmost surface of the second doped layer is above a top surface of the second inner spacer. In some embodiments, a germanium concentration of the second doped layer is higher than a germanium concentration of the first doped layer, and a dopant concentration of the second doped layer is higher than a dopant concentration of the first doped layer. In some embodiments, the method may also include forming a conductive feature disposed under and electrically couple to the first source/drain feature, wherein a top surface of the conductive feature is above a top surface of the second portion of the first doped layer. In some embodiments, the method may also include forming a doped silicon layer disposed between the first portion of the first doped layer and the lower channel layer. In some embodiments, the method may also include forming an isolation structure disposed between the first source/drain feature and the second source/drain feature.

In another exemplary aspect, the present disclosure is directed to a method. The method includes forming a fin-shaped structure over a substrate, the fin-shaped structure comprising a vertical stack of alternating channel layers and sacrificial layers over a substrate, forming a source/drain opening extending through the fin-shaped structure, selectively recessing the channel layers without substantially etching the sacrificial layers to enlarge the source/drain opening, forming a source/drain feature in the source/drain opening and adjoining the recessed channel layers, and replacing the sacrificial layers with a gate structure.

In some embodiments, the method may also include before the selectively recessing of the channel layers, forming inner spacers adjoining the sacrificial layers. In some embodiments, a bottom surface of the enlarged source/drain opening has a first crystal plane orientation and a side surface of the enlarged source/drain opening has a second crystal plane orientation different from the first crystal plane orientation. In some embodiments, the forming of the source/drain feature may include performing a growth process to form an epitaxial layer, and a growth rate of the epitaxial layer on the side surface is lower than a growth rate of the epitaxial layer on the bottom surface. In some embodiments, upon completion of the performing of the growth process, the epitaxial layer may include a first portion laterally adjacent to the channel layers and a second portion disposed under the channel layers, and the first portion and the second portion are physically separated. In some embodiments, the epitaxial layer is a first epitaxial layer, and the source/drain feature may also include a second epitaxial layer over the first epitaxial layer, the method may also include performing an etching process to remove a portion of the substrate disposed under the source/drain feature and the second portion of the first epitaxial layer to expose a bottom surface of the second epitaxial layer, thereby forming a trench, and forming a conductive feature in the trench.

In yet another exemplary aspect, the present disclosure is directed to a semiconductor device. The semiconductor device includes a lower source/drain feature disposed over a substrate, a first nanostructure coupled to the lower source/drain feature, a first gate structure wrapping around the first nanostructure, an upper source/drain feature over the lower source/drain feature, a second nanostructure coupled to the upper source/drain feature, and a second gate structure wrapping around the second nanostructure, a width of the lower source/drain feature is greater than a width of the upper source/drain feature.

In some embodiments, the semiconductor device may also include an inner spacer adjoining the first gate structure, the inner spacer extends over a portion of the lower source/drain feature. In some embodiments, the lower source/drain feature may include a first epitaxial layer adjoining the first nanostructure, and a second epitaxial layer adjoining the first epitaxial layer, wherein a dopant concentration of the second epitaxial layer is greater than a dopant concentration of the first epitaxial layer, and a portion of the second epitaxial layer extends over the inner spacer. In some embodiments, the semiconductor device may also include a source/drain contact disposed under and electrically coupled to the lower source/drain feature and a silicide layer sandwiched by the source/drain contact and the second epitaxial layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor layer stack over a substrate, the semiconductor layer stack having an upper channel layer over a lower channel layer;
performing an etching process to laterally recess the lower channel layer without substantially etching the upper channel layer;
forming a first source/drain feature coupled to the recessed lower channel layer; and
forming a second source/drain feature coupled to the upper channel layer, the second source/drain feature is disposed over the first source/drain feature.

2. The method of claim 1, wherein the first source/drain feature spans a first width, the second source/drain feature spans a second width less than the first width.

3. The method of claim 1, further comprising:
forming a first inner spacer under the lower channel layer and a second inner spacer over the lower channel layer,
wherein the laterally recessing of the lower channel layer forms a groove exposing a bottom surface of the second inner spacer and a top surface of the first inner spacer.

4. The method of claim 3, wherein the first source/drain feature comprises a doped layer having a first portion in the groove and a second portion disposed below the first inner spacer, wherein the first portion of the doped layer partially fills the groove.

5. The method of claim 4, wherein a thickness of the second portion is greater than a thickness of the first portion.

6. The method of claim 4, wherein the doped layer is a first doped layer, and the first source/drain feature further comprises a second doped layer, wherein the second doped layer extends into the groove, and a topmost surface of the second doped layer is above a top surface of the second inner spacer.

7. The method of claim 6, wherein a germanium concentration of the second doped layer is higher than a germanium concentration of the first doped layer, and a dopant concentration of the second doped layer is higher than a dopant concentration of the first doped layer.

8. The method of claim 6, further comprising:
forming a conductive feature disposed under and electrically couple to the first source/drain feature, wherein a top surface of the conductive feature is above a top surface of the second portion of the first doped layer.

9. The method of claim 6, further comprising:
forming a doped silicon layer disposed between the first portion of the first doped layer and the lower channel layer.

10. The method of claim 1, further comprising:
forming an isolation structure disposed between the first source/drain feature and the second source/drain feature.

11. A method, comprising:
forming a fin-shaped structure over a substrate, the fin-shaped structure comprising a vertical stack of alternating channel layers and sacrificial layers over a substrate;
forming a source/drain opening extending through the fin-shaped structure;
selectively recessing the channel layers without substantially etching the sacrificial layers to enlarge the source/drain opening;
forming a source/drain feature in the source/drain opening and adjoining the recessed channel layers; and
replacing the sacrificial layers with a gate structure.

12. The method of claim 11, further comprising:
before the selectively recessing of the channel layers, forming inner spacers adjoining the sacrificial layers.

13. The method of claim 11, wherein a bottom surface of the enlarged source/drain opening has a first crystal plane orientation and a side surface of the enlarged source/drain opening has a second crystal plane orientation different from the first crystal plane orientation.

14. The method of claim 13, wherein the forming of the source/drain feature comprises performing a growth process to form an epitaxial layer, wherein a growth rate of the epitaxial layer on the side surface is lower than a growth rate of the epitaxial layer on the bottom surface.

15. The method of claim 14, wherein, upon completion of the performing of the growth process, the epitaxial layer comprises a first portion laterally adjacent to the channel layers and a second portion disposed under the channel layers, and the first portion and the second portion are physically separated.

16. The method of claim 15, wherein the epitaxial layer is a first epitaxial layer, and the source/drain feature further comprises a second epitaxial layer over the first epitaxial layer, the method further comprises:
performing an etching process to remove a portion of the substrate disposed under the source/drain feature and the second portion of the first epitaxial layer to expose a bottom surface of the second epitaxial layer, thereby forming a trench; and
forming a conductive feature in the trench.

17. A semiconductor device, comprising:
a lower source/drain feature disposed over a substrate;
a first nanostructure coupled to the lower source/drain feature;
a first gate structure wrapping around the first nanostructure;
an upper source/drain feature over the lower source/drain feature;
a second nanostructure coupled to the upper source/drain feature; and
a second gate structure wrapping around the second nanostructure,
wherein a width of the lower source/drain feature is greater than a width of the upper source/drain feature.

18. The semiconductor device of claim 17, further comprising:
an inner spacer adjoining the first gate structure,
wherein the inner spacer extends over a portion of the lower source/drain feature.

19. The semiconductor device of claim 18, wherein the lower source/drain feature comprises:
a first epitaxial layer adjoining the first nanostructure; and
a second epitaxial layer adjoining the first epitaxial layer, wherein a dopant concentration of the second epitaxial layer is greater than a dopant concentration of the first epitaxial layer, and a portion of the second epitaxial layer extends over the inner spacer.

20. The semiconductor device of claim 19, further comprising:
a source/drain contact disposed under and electrically coupled to the lower source/drain feature; and
a silicide layer sandwiched by the source/drain contact and the second epitaxial layer.
